(19) United States
(12) Patent Application Publication
(10) Pub. No.: US 2025/0393457 A1
(43) Pub. Date: Dec. 25, 2025

(54) DISPLAY DEVICE, SUBSTRATE, AND ELECTRONIC DEVICE INCLUDING THE SAME

(71) Applicant: Samsung Display Co., LTD., Yongin-si (KR)

(72) Inventor: Jong Duk ROH, Yongin-si (KR)

(21) Appl. No.: 19/094,863

(22) Filed: Mar. 29, 2025

(30) Foreign Application Priority Data
Jun. 19, 2024 (KR) 10-2024-0079513
Jul. 12, 2024 (KR) 10-2024-0092683

(51) Int. Cl. H10K 59/88; H10K 59/122

(52) U.S. Cl. CPC H10K 59/88; H10K 59/122

(57) ABSTRACT

A display device includes a base layer including a marking code; a first electrode on the base layer; a light emitting structure on the first electrode; and a second electrode on the light emitting structure, where the marking code includes dot patterns including an embossed pattern and an engraved pattern, and a depth of the engraved pattern with respect to a surface of the base layer is greater than a height of the embossed pattern with respect to the surface of the base layer.

This application claims priority to Korean Patent Application No. 10-2024-0079513, filed on Jun. 19, 2024, and Korean Patent Application No. 10-2024-0092683, filed on Jul. 12, 2024, and all the benefits accruing therefrom under 35 U.S.C. § 119, the contents of which in their entireties are herein incorporated by reference.

### BACKGROUND

### (1) Field

Embodiments of the disclosure relate to a display device a substrate, and an electronic device the same.

### (2) Description of the Related Art

Recently, interest in information displays has been increased, and accordingly, research and development on the display devices are continuously conducted.

### SUMMARY

Embodiments of the disclosure is to increase a recognition rate of a marking code formed in a display device.

An embodiment provides a display device including: a base layer including a marking code; a first electrode on the base layer; a light emitting structure on the first electrode; and a second electrode on the light emitting structure, where the marking code includes dot patterns including an embossed pattern and an engraved pattern, and a depth of the engraved pattern with respect to a surface of the base layer is greater than a height of the embossed pattern with respect to the surface of the base layer.

In an embodiment, the height of the embossed pattern may be less than about 0.5 micrometer (μm).

In an embodiment, the depth of the engraved pattern may be less than about 1 μm.

In an embodiment, a width of each of the dot patterns may be in a range of about 8 μm to about 12 μm.

In an embodiment, an interval between the dot patterns may be about 1.2 μm or less.

In an embodiment, the dot patterns may be arranged in a first direction and a second direction intersecting the first direction.

In an embodiment, the embossed pattern may surround the engraved pattern on a plane.

In an embodiment, the base layer may be a silicon substrate.

In an embodiment, the display device may further include a pixel definition layer between the first electrode and the light emitting structure.

In an embodiment, the light emitting structure may be disposed entirely on the first electrode and the pixel definition layer.

In an embodiment, the pixel definition layer may include a separator.

In an embodiment, the light emitting structure may be at least partially separated by the separator.

In an embodiment, ash, burrs, and/or particles may not exist in the marking code.

Another embodiment provides a substrate including: a marking code configured with dot patterns including an embossed pattern and an engraved pattern, where a depth of the engraved pattern with respect a surface of the substrate is greater than a height of the embossed pattern with respect the surface of the substrate.

In an embodiment, the height of the embossed pattern may be less than about 0.5 μm.

In an embodiment, the depth of the engraved pattern may be less than about 1 μm.

In an embodiment, a width of each of the dot patterns may be in a range of about 8 μm to about 12 μm.

In an embodiment, an interval between the dot patterns may be 1.2 μm or less.

In an embodiment, the dot patterns may be arranged in a first direction and a second direction intersecting the first direction.

In an embodiment, the embossed pattern may surround the engraved pattern on a plane.

In an embodiment, the base layer may be a silicon substrate.

In an embodiment, ash, burrs, and/or particles may not exist in the marking code.

An embodiment provides an electronic device including: a processor to provide input image data; and a display device to display an image based on the input image data, the display device including sub-pixel areas, wherein the display device comprises a base layer including a marking code; a first electrode on the base layer; a light emitting structure on the first electrode; and a second electrode on the light emitting structure, where the marking code includes dot patterns including an embossed pattern and an engraved pattern, and a depth of the engraved pattern with respect to a surface of the base layer is greater than a height of the embossed pattern with respect to the surface of the base layer.

According to embodiments of the disclosure, as described herein, dot patterns of a marking code are formed through laser annealing, and thus, it is possible to effectively prevent laser residue from being generated and to effectively prevent a recognition rate of the marking code from being reduced.

The effects according to the embodiments are not limited to those described above, and more diverse effects are included in the specification.

### BRIEF DESCRIPTION OF THE DRAWINGS

FIG. 1 is a block diagram illustrating an embodiment of a display device.

FIG. 2 is a block diagram illustrating an embodiment of one of sub-pixels of FIG. 1.

FIG. 3 is a circuit diagram illustrating an embodiment of a sub-pixel of FIG. 2.

FIG. 4 is a plan view illustrating an embodiment of a display panel of FIG. 1.

FIG. 5 is a plan view illustrating an embodiment of a marking code of FIG. 4.

FIG. 6 is a plan view illustrating an embodiment of dot patterns of FIG. 5.

FIG. 7 and FIG. 8 are cross-sectional views taken along line A-A′ of FIG. 6.

FIG. 9 is a photograph illustrating dot patterns according to a comparative example.

FIG. 10 is a photograph illustrating dot patterns according to an embodiment.

FIG. 11 is an exploded perspective view illustrating a part of the display panel of FIG. 4.

FIG. 12 is a plan view illustrating an embodiment of one of pixels of FIG. 11.

FIG. 13 is a cross-sectional view taken along line B-B′ of FIG. 12.

FIG. 14 is a cross-sectional view taken along line B-B′ of FIG. 12.

FIG. 15 is an enlarged view illustrating a region A of FIG. 14.

FIG. 16 is a cross-sectional view illustrating an embodiment of a part of a light emitting structure included in one of first to third light emitting elements of FIG. 13 or FIG. 14.

FIG. 17 is a cross-sectional view illustrating another embodiment of a part of the light emitting structure included in one of the first to third light emitting elements of FIG. 13 or FIG. 14.

FIG. 18 is a plan view illustrating another embodiment of one of pixels of FIG. 11.

FIG. 19 is a plan view illustrating another embodiment of one of the pixels of FIG. 11.

FIG. 20 is a block diagram illustrating an embodiment of a display system.

FIG. 21 is a perspective view illustrating an application example of the display system of FIG. 20.

FIG. 22 is a view illustrating a head-mounted display device worn by a user of FIG. 21.

FIG. 23 is a perspective view illustrating another application example of the display system of FIG. 20.

FIG. 24 and FIG. 25 are cross-sectional views of processes of a manufacturing method of a display device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. Throughout the specification, when a part is said to be “connected” to another part, this includes not only a case where the part is “directly connected” thereto but also a case where the part is “indirectly connected” thereto with another element therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. “At least one of X, Y, and Z”, or “at least one selected from X, Y, and Z” may be interpreted as one X, one Y, one Z, or any combination (for example, XYZ, XYY, YZ, or ZZ) of two or more of X, Y, and Z. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “below”, “above,” and so on, may be used for descriptive purposes, thereby describing a relationship of one element or feature to another element(s) or feature(s) as illustrated in the drawings. The spatially relative terms are intended to include different directions in use, operation, and/or manufacturing, in addition to the direction illustrated in the drawings. For example, when the device illustrated in the drawing is turned over, components described as being placed “below” other components or features are placed “above” the other components or features. Therefore, in one embodiment, the term “below” may include both above and below. Furthermore, the device may be oriented in another direction (for example, rotated 90 degrees or in another direction), and the spatially relative terms used herein are interpreted according thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

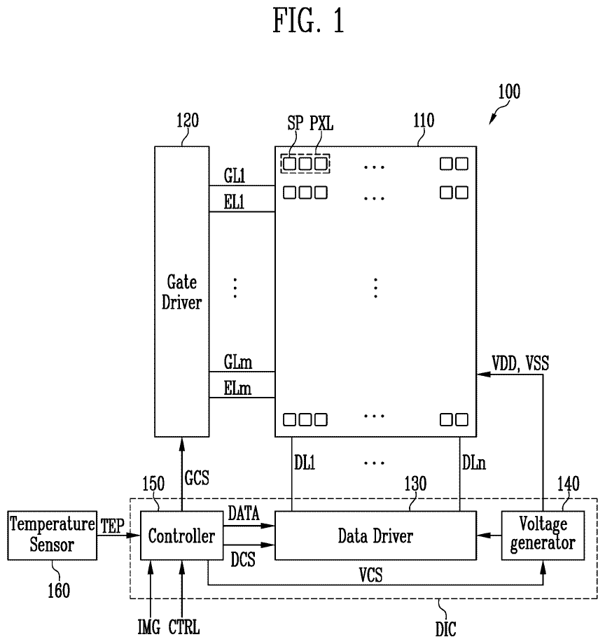

FIG. 1 is a block diagram illustrating an embodiment of a display device.

Referring to FIG. 1, an embodiment of a display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Here, n and m are natural numbers.

Each of the sub-pixels SP may include at least one light emitting element configured to generate light. Accordingly, each of the sub-pixels SP may generate light of a specific color, such as red, green, blue, cyan, magenta, yellow, and so on. In an embodiment, two or more sub-pixels among the sub-pixels SP may constitute one pixel PXL. In an embodiment, for example, as illustrated in FIG. 1, three sub-pixels may constitute one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal for instructing the start of each frame, a horizontal synchronization signal for outputting the gate signals in synchronization with timing at which data signals are applied, or the like.

In an embodiment, first to m-th light emission control lines EL1 to ELm connected to the sub-pixels SP in the row direction may be further provided. In such an embodiment, the gate driver 120 may include a light emission control driver configured to control the first to m-th light emission control lines EL1 to ELm, and the light emission control driver may operate under the control of the controller 150.

In an embodiment, as shown in FIG. 1, the gate driver 120 may be disposed on one side of the display panel 110. However, embodiments are not limited thereto. In another embodiment, for example, the gate driver 120 may be divided into two or more drivers that are physically and/or logically separated, and the drivers may be disposed on one side of the display panel 110 and the other side of the display panel 110 opposite to the one side. In this way, the gate driver 120 may be disposed on the periphery of the display panel 110 in various forms according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to a data control signal DCS. In the embodiment, the data control signal DCS may include a source start pulse, a source shift clock, a source output enable signal, or the like.

The data driver 130 may apply data signals having grayscale voltages corresponding to the image data DATA to the first to n-th data lines DL1 to DLn by using voltages from the voltage generator 140. When a gate signal is applied to each of the first to m-th gate lines GL1 to GLm, data signals corresponding to the image data DATA may be applied to the data lines DL1 to DLn. Accordingly, the corresponding sub-pixels SP may generate light corresponding to the data signals. Accordingly, an image is displayed on the display panel 110.

In an embodiment, the gate driver 120 and the data driver 130 may each include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device 100. In an embodiment, for example, the voltage generator 140 may generate the plurality of voltages by receiving an input voltage from the outside of the display device 100, adjusting the received voltage, and regulating the adjusted voltage.

The voltage generator 140 may generate a first power supply voltage VDD and a second power supply voltage VSS, and the generated first and second power supply voltages VDD and VSS may be provided to the sub-pixels SP. The first power supply voltage VDD may have a relatively high voltage level, and the second power supply voltage VSS may have a lower voltage level than the first power supply voltage VDD. In another embodiment, the first power supply voltage VDD or the second power supply voltage VSS may be provided by an external device of the display device 100.

In addition, the voltage generator 140 may generate various voltages. In an embodiment, for example, the voltage generator 140 may generate an initialization voltage applied to the sub-pixels SP. In an embodiment, for example, during a sensing operation for sensing electrical characteristics of transistors and/or light emitting elements of the sub-pixels SP, a predetermined reference voltage may be applied to the first to n-th data lines DL1 to DLn, and the voltage generator 140 may generate the reference voltage.

The controller 150 controls all operations of the display device 100. The controller 150 receives input image data IMG and a control signal CTRL for controlling display of the image data IMG from an outside (or an external device). The controller 150 may generate a gate control signal GCS, a data control signal DCS, and a voltage control signal VCS in response to the control signal CTRL.

The controller 150 may convert the input image data IMG to be suitable for the display device 100 or the display panel 110 and output the converted image data DATA. In an embodiment, the controller 150 may align the input image data IMG to be suitable for the sub-pixels SP of a row unit and output the image data DATA.

In an embodiment, two or more of the data driver 130, the voltage generator 140, and the controller 150 may be mounted on a single integrated circuit. In an embodiment, as illustrated in FIG. 1, the data driver 130, the voltage generator 140, and the controller 150 may be included in a driver integrated circuit DIC. In such an embodiment, the data driver 130, the voltage generator 140, and the controller 150 may be functionally separate components in a single driver integrated circuit DIC. In another embodiment, at least one of the data driver 130, the voltage generator 140, and the controller 150 may be provided as a separate component from the driver integrated circuit DIC.

The display device 100 may include at least one temperature sensor 160. The temperature sensor 160 is configured to detect temperature around the temperature sensor 160 and to generate temperature data TEP representing the detected temperature. In an embodiment, the temperature sensor 160 may be disposed to be adjacent to the display panel 110 and/or the driver integrated circuit DIC.

The controller 150 may control various operations of the display device 100 in response to the temperature data TEP. In an embodiment, the controller 150 may control the brightness of an image output from the display panel 110 in response to the temperature data TEP. In an embodiment, for example, the controller 150 may control components, such as the data driver 130 and/or the voltage generator 140, to control data signals and the first power supply voltage VDD and the second power supply voltage VSS.

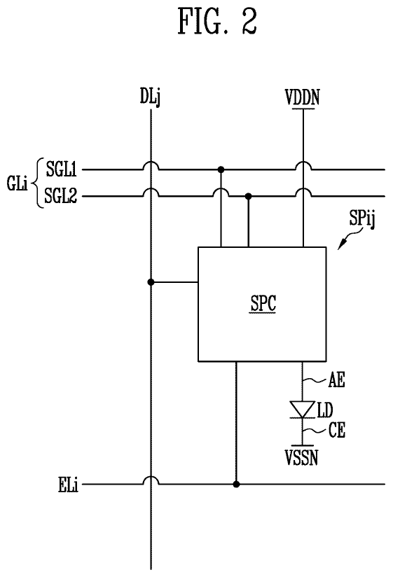

FIG. 2 is a block diagram illustrating an embodiment of one of the sub-pixels of FIG. 1. For convenience of illustration and description, FIG. 2 illustrates a sub-pixel SPij arranged in the i-th row (i is an integer greater than or equal to 1 and less than or equal to m) and the j-th column (j is an integer greater than or equal to 1 and less than or equal to n) among the sub-pixels SP of FIG. 1 as an example.

Referring to FIG. 2, an embodiment of the sub-pixel SPij may include a sub-pixel circuit SPC and a light emitting element LD.

In an embodiment, the light emitting element LD is connected between a first power supply voltage node VDDN and a second power supply voltage node VSSN. In such an embodiment, the first power supply voltage node VDDN is a node through which the first power supply voltage VDD of FIG. 1 is transferred, and the second power supply voltage node VSSN is a node through which the second power supply voltage VSS of FIG. 1 is transferred.

An anode electrode AE of the light emitting element LD may be connected to the first power voltage node VDDN through the sub-pixel circuit SPC, and a cathode electrode CE of the light emitting element LD may be connected to the second power voltage node VSSN. In an embodiment, for example, the anode electrode AE of the light emitting element LD may be connected to the first power voltage node VDDN through one or more transistors included in the sub-pixel circuit SPC.

The sub-pixel circuit SPC may be connected to the i-th gate line GLi among the first to m-th gate lines GL1 to GLm of FIG. 1, the i-th light emitting control line ELi among the first to m-th light emitting control lines EL1 to ELm of FIG. 1, and the j-th data line DLj among the first to n-th data lines DL1 to DLn of FIG. 1. The sub-pixel circuit SPC is configured to control the light emitting element LD in response to signals received through the signal lines.

The sub-pixel circuit SPC may operate in response to a gate signal received through the i-th gate line GLi. The i-th gate line GLi may include one or more sub-gate lines. In an embodiment, as illustrated in FIG. 2, the i-th gate line GLi may include first and second sub-gate lines SGL1 and SGL2. The sub-pixel circuit SPC may operate in response to gate signals received through the first sub-gate line SGL1 and the second sub-gate line SGL2. In such an embodiment, where the i-th gate line GLi includes two or more sub-gate lines, the sub-pixel circuit SPC may operate in response to gate signals received through corresponding sub-gate lines.

The sub-pixel circuit SPC may operate in response to an emission control signal received through the i-th emission control line ELi. In an embodiment, the i-th emission control line ELi may include one or more sub-emission control lines. In such an embodiment where the i-th emission control line ELi includes two or more sub-emission control lines, the sub-pixel circuit SPC may operate in response to the emission control signals received through corresponding sub-emission control lines.

The sub-pixel circuit SPC may receive a data signal through the j-th data line DLj. The sub-pixel circuit SPC may store a voltage corresponding to the data signal in response to at least one of the gate signals received through the first sub-gate line SGL1 and the second sub-gate line SGL2. The sub-pixel circuit SPC may control a current flowing from the first power voltage node VDDN to the second power voltage node VSSN through the light emitting element LD based on the stored voltage in response to the light emitting control signal received through the i-th light emitting control line ELi. Accordingly, the light emitting element LD may generate light of brightness corresponding to the data signal.

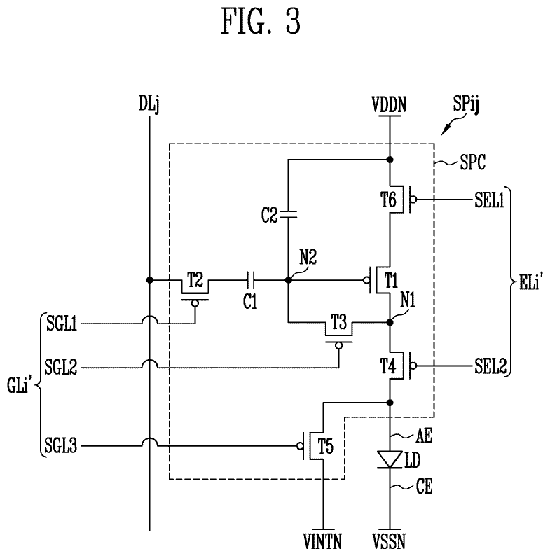

FIG. 3 is a circuit diagram illustrating an embodiment of the sub-pixel of FIG. 2.

Referring to FIG. 3, an embodiment of the sub-pixel SPij may include the sub-pixel circuit SPC and the light emitting element LD.

The sub-pixel circuit SPC may be connected to an i-th gate line GLi′, an i-th light emitting control line ELi′, and a j-th data line DLj. In an embodiment, as shown in FIG. 3, the i-th gate line GLi′ may further include a third sub-gate line SGL3. In such an embodiment, the i-th light emission control line ELi′ may include a first sub-light emission control line SEL1 and a second sub-light emission control line SEL2.

The sub-pixel circuit SPC may include first to sixth transistors T1 to T6, and first and second capacitors C1 and C2.

The first transistor T1 is connected between the first power supply voltage node VDDN and a first node N1. A gate of the first transistor T1 is connected to a second node N2, and accordingly, the first transistor T1 may turn on based on a voltage level of the second node N2. The first transistor T1 may be referred to as a drive transistor.

The second transistor T2 is connected between the j-th data line DLj and the second node N2. A gate of the second transistor T2 may be connected to the first sub-gate line SGL1, and accordingly, the second transistor T2 may turn on in response to a gate signal of the first sub-gate line SGL1. The second transistor T2 may be referred to as a switching transistor.

The third transistor T3 is connected between the first node N1 and the second node N2. A gate of the third transistor T3 may be connected to the second sub-gate line SGL2, and accordingly, the third transistor T3) may turn on in response to a gate signal of the second sub-gate line SGL2.

The fourth transistor T4 is connected between the first node N1 and the anode electrode AE of the light emitting element LD. A gate of the fourth transistor T4 may be connected to the second sub-light emitting control line SEL2, and accordingly, the fourth transistor T4 may turn on in response to a light emitting control signal of the second sub-light emitting control line SEL2.

The fifth transistor T5 is connected between the anode electrode AE of the light emitting element LD and an initialization voltage node VINTN. The initialization voltage node VINTN is configured to transmit an initialization voltage. In the embodiment, the initialization voltage may be provided by the voltage generator 140 of FIG. 1. In another embodiment, the initialization voltage may be provided by a device external to the display device 100. A gate of the fifth transistor T5 may be connected to the third sub-gate line SGL3, and accordingly, the fifth transistor T5 may turn on in response to a gate signal of the third sub-gate line SGL3.

The sixth transistor T6 is connected between the first power supply voltage node VDDN and the first transistor T1. A gate of the sixth transistor T6 may be connected to the first sub-emission control line SEL1, and accordingly, the sixth transistor T6 may turn on in response to an emission control signal of the first sub-emission control line SEL1.

The first capacitor C1 is connected between the second transistor T2 and the second node N2. The second capacitor C2 is connected between the first power supply voltage node VDDN and the second node N2.

In an embodiment, as shown in FIG. 3, the sub-pixel circuit SPC may include the first to sixth transistors T1 to T6, the first capacitor C1, and the second capacitors C2. However, embodiments are not limited thereto. The sub-pixel circuit SPC may be implemented by any one of various types of circuits including a plurality of transistors and one or more capacitors. In an embodiment, for example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may be changed.

In an embodiment, the first to sixth transistors T1 to T6 may be P-type transistors. The second capacitor C2 may be connected between the first power supply voltage node VDDN and the second node N2. However, embodiments are not limited thereto. In another embodiment, for example, at least one of the first to sixth transistors T1 to T6 may be replaced with N-type transistors.

In an embodiment, the first to sixth transistors T1 to T6 may each include an amorphous silicon semiconductor, a monocrystalline silicon semiconductor, a polycrystalline silicon semiconductor, an oxide semiconductor, or so on.

The light emitting element LD may include the anode electrode AE, the cathode electrode CE, and alight emitting layer. The light emitting layer may be disposed between the anode electrode AE and the cathode electrode CE. After the data signal transmitted through the j data line DLj is reflected in a voltage of the second node N2, the fourth and sixth transistors T4 and T6 may turn on when the light emission control signals of the first and second sub-light emission control lines SEL1 and SEL2 are enabled to a low voltage level. In addition, the first transistor T1 may turn on based on the voltage of the second node N2, and accordingly, a current may flow from the first power voltage node VDDN to the second power voltage node VSSN. The light emitting element LD may emit light corresponding to the amount of a flowing current.

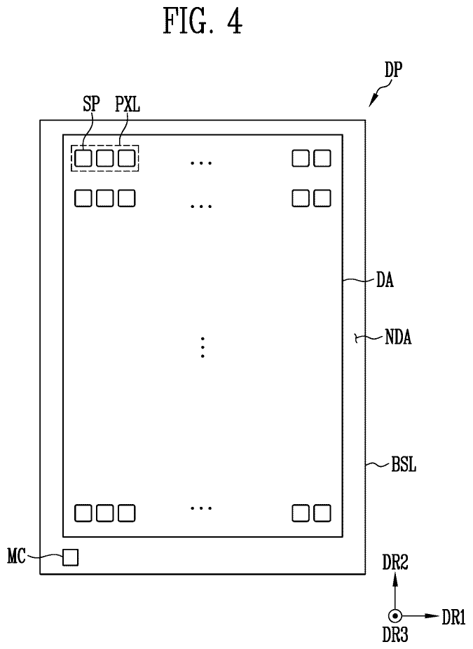

FIG. 4 is a plan view illustrating an embodiment of the display panel 110 of FIG. 1.

Referring to FIG. 4, an embodiment of the display panel DP (corresponding to the display panel 110 of FIG. 1) may include a display region DA and a non-display region NDA. The display panel DP displays an image through the display region DA. The non-display region NDA is disposed around the display region DA. In an embodiment, the display region DA may have various shapes. The display region DA may have a shape of a closed loop including straight and/or curved edges. In an embodiment, for example, the display region DA may have shapes, such as a polygon, a circle, a semicircle, and an ellipse.

In an embodiment, the display panel DP may have a flat display surface. In another embodiment, the display panel DP may have a display surface which is at least partially rounded. In an embodiment, the display panel DP may be bendable, foldable, or rollable. In such an embodiment, the display panel DP and/or a base layer BSL may include flexible materials.

In an embodiment where the display panel DP is used as a display screen of a smart watch, a head-mounted display (HMD), a virtual reality (VR) device, a mixed reality (MR) device, an augmented reality (AR) device, or so on, relatively highly integrated sub-pixels SP are desired. In such an embodiment, the base layer BSL may be provided as a silicon substrate to increase the degree of integration of the sub-pixels SP. The sub-pixels SP and/or the display panel DP may be formed in the base layer BSL, which is a silicon substrate. Here, the display device 100 (see FIG. 1) including the display panel DP formed in the base layer BSL, which is a silicon substrate, may be referred to as an organic light emitting diode (OLED) on silicon (OLEDoS) display device.

The sub-pixels SP is disposed in a display region DA of the base layer BSL. The sub-pixels SP may be arranged in a matrix form in a first direction DR1 and a second direction DR2 intersecting the first direction DR1. However, embodiments are not limited thereto. In an embodiment, for example, the sub-pixels SP may be arranged in a zigzag form in the first direction DR1 and the second direction DR2. In an embodiment, for example, the sub-pixels SP may be disposed in a pentile type. The first direction DR1 may be a row direction, and the second direction DR2 may be a column direction.

Two or more of the plurality of sub-pixels SP may constitute one pixel PXL.

Components for controlling the sub-pixels SP may be disposed in the non-display region NDA on the base layer BSL. In an embodiment, for example, wires connected to the sub-pixels SP, such as the first to m-th gate lines GL1 to GLm and the first to n-th data lines DL1 to DLn of FIG. 1, may be disposed in the non-display region NDA.

At least one selected from the gate driver 120, the data driver 130, the voltage generator 140, the controller 150, and the temperature sensor 160 of FIG. 1 may be integrated to the non-display region NDA of the display panel DP. In an embodiment, the gate driver 120 of FIG. 1 may be mounted on the display panel DP but may be disposed in the non-display region NDA. In another embodiment, the gate driver 120 may be implemented as an integrated circuit separate from the display panel DP. In an embodiment, the temperature sensor 160 may be placed in a non-display region NDA to detect the temperature of the display panel 110.

In an embodiment, the base layer BSL may include a marking code MC. The marking code MC may be located in a non-display region NDA of the base layer BSL. The marking code MC may include identification information of the display panel 110.

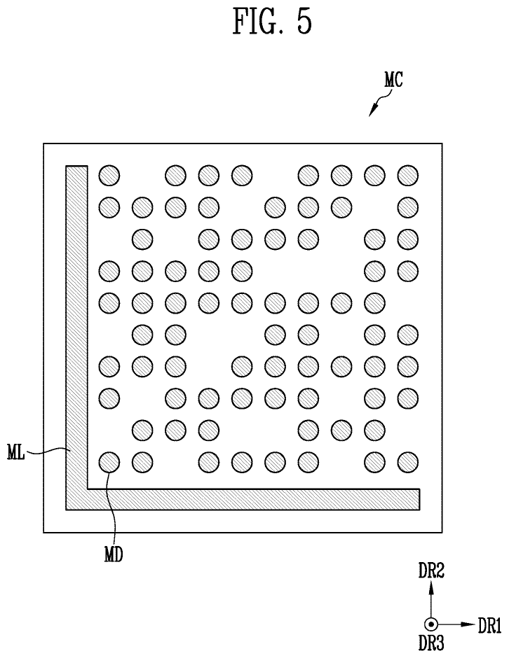

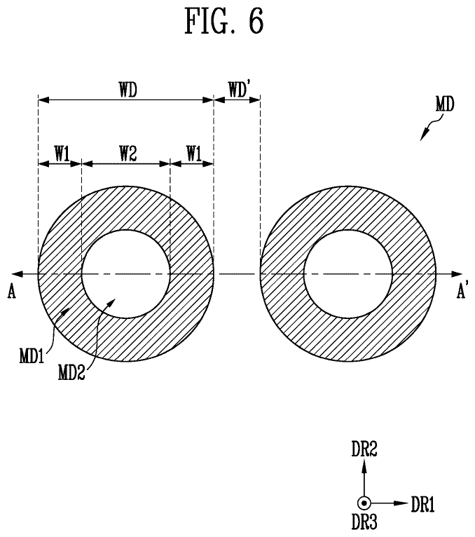

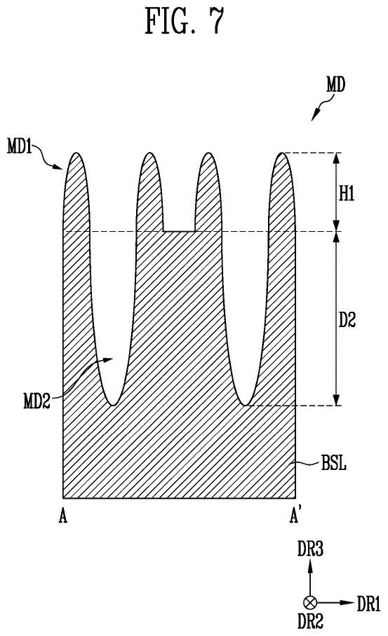

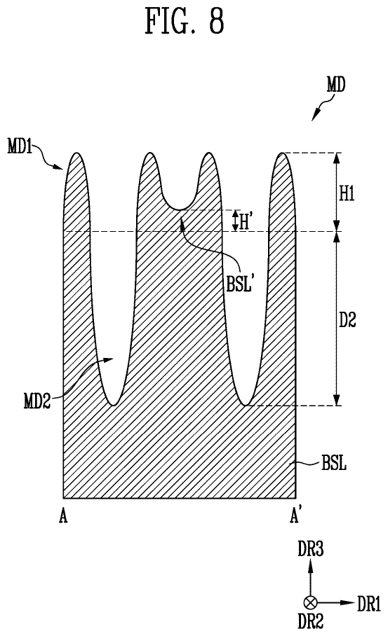

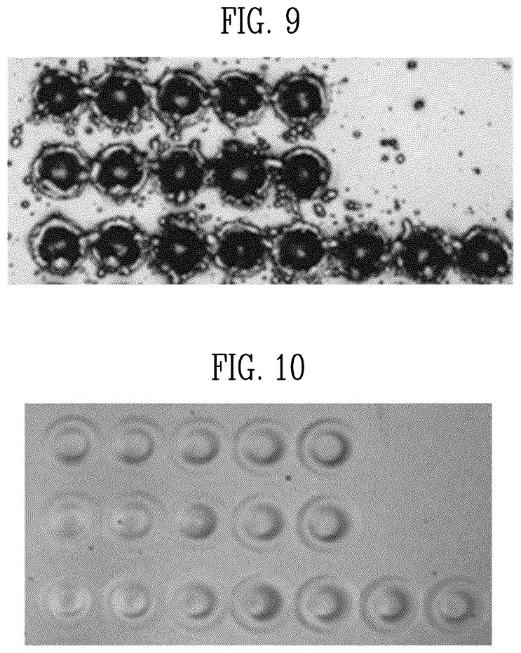

FIG. 5 is a plan view illustrating an embodiment of the marking code MC of FIG. 4. FIG. 6 is a plan view illustrating an embodiment of a dot pattern of FIG. 5. FIG. 7 and FIG. 8 are cross-sectional views taken along line A-A′ of FIG. 6. FIG. 9 is a photograph illustrating dot patterns according to a comparative example. FIG. 10 is a photograph illustrating dot patterns according to an embodiment.

Referring to FIGS. 5 to 8, in an embodiment, the marking code MC may include dot patterns MD. The dot patterns MD may be arranged in the first direction DR1 and/or the second direction DR2. The dot patterns MD may each have a circular shape on a plane or in a plan view. A width WD (or a diameter) of each of the dot patterns MD may be in a range of about 8 micrometers (μm) to about 12 μm. The dot patterns MD may be separated from each other. An interval WD′ between the dot patterns MD may be about 10% or less of the width WD of each of the dot patterns MD. In an embodiment, for example, the interval WD′ between the dot patterns MD may be about 0.8 μm or less. Alternatively, the interval WD′ between the dot patterns MD may be about 1.2 μm or less. If the interval WD′ between the dot patterns MD is formed to be greater than about 10% of the width WD of each of the dot patterns MD, a recognition rate of the marking code MC may be reduced. However, the shapes and arrangement of the dot patterns MD are not limited thereto, and the shapes and arrangement of the dot patterns MD may be changed within a range where the recognition rate of the marking code MC is not reduced.

In an embodiment, as shown in FIGS. 6 and 7, the dot patterns MD may each include an embossed pattern MD1 and an engraved pattern MD2. The embossed pattern MD1 may surround the engraved pattern MD2 on a plane. The engraved pattern MD2 may have a circular shape on a plane. The embossed pattern MD1 may have a round border (or a ring-like) shape surrounding an edge of the engraved pattern MD2 on a plane. A width W1 of the embossed pattern MD1 may be less than a width W2 of the engraved pattern MD2 but is not limited thereto.

The embossed pattern MD1 may have a shape protruding from one surface (or an upper surface) of the base layer BSL in the third direction DR3 in a cross-section. A height H1 of the embossed pattern MD1 with respect to one surface (or an upper surface) of the base layer BSL in the third direction DR3 may be less than about 0.5 μm. If the height H1 of the embossed pattern MD1 in the third direction DR3 is formed to be greater than about 0.5 μm, contamination may be generated due to laser residue during a process of forming the marking code MC, or a recognition rate of the marking code MC may be reduced.

The engraved pattern MD2 may have a shape that is recessed in the third direction DR3 from one surface or an upper surface of the base layer BSL in a cross-section. A depth D2 of the engraved pattern MD2 with respect to one surface (or an upper surface) of the base layer BSL in the third direction DR3 may be less than about 1 μm. If the depth D2 of the engraved pattern MD2 in the third direction DR3 is formed to be greater than about 1 μm, contamination may be generated due to laser residue during a process of forming the marking code MC, or a recognition rate of the marking code MC may be reduced. In an embodiment, the depth D2 of the engraved pattern MD2 in the third direction DR3 may be formed to be greater than the height H1 of the embossed pattern MD1 in the third direction DR3, but is not limited thereto.

In an embodiment, the marking code MC may further include a line pattern ML. The line pattern ML may include a first line portion extending in the first direction DR1 and a second line portion extending in the second direction DR2. In an embodiment, for example, the first line portion may be located adjacent to one side (below or to a bottom side) of the marking code MC, and the second line portion may be located adjacent to another side (e.g., to the left or to a left side) of the marking code MC but are not limited thereto.

In an embodiment, as illustrated in FIG. 7, the embossed patterns MD1 of the dot patterns MD may be separated from each other. The base layer BSL may be disposed between the embossed patterns MD1 of the dot patterns MD. However, the embodiment is not limited thereto, and as illustrated in FIG. 8, a base portion BSL′ may be disposed between the embossed patterns MD1 of the dot patterns MD. A height H′ of the base portion BSL′ with respect to one surface (or an upper surface) of the base layer BSL in the third direction DR3 may be less than the height H1 of the embossed pattern MD1 with respect to one surface (or an upper surface) of the base layer BSL in the third direction DR3 but is not limited thereto.

In an embodiment, the above-described dot patterns MD may be formed through laser annealing. In such an embodiment where the dot patterns MD are formed through the laser annealing, it is possible to effectively prevent laser residue from being generated. For example, FIG. 9 illustrates dot patterns according to a comparative example, which are formed by using laser ablation, and it can be seen that laser residues, that is, ash, burrs, particles, and/or so on, are generated in the marking code (the dot patterns and surroundings thereof). FIG. 10 illustrates dot patterns according to an embodiment of the disclosure, which are formed through laser annealing, and it can be seen that laser residues, that is, ash, burrs, particles, and/or so on, do not exist in the marking code (the dot patterns and surroundings thereof). Therefore, in an embodiment where the dot patterns MD are formed through laser annealing, it is possible to effectively prevent contamination from being generated due to laser residue and to prevent a recognition rate of the marking code MC from being reduced.

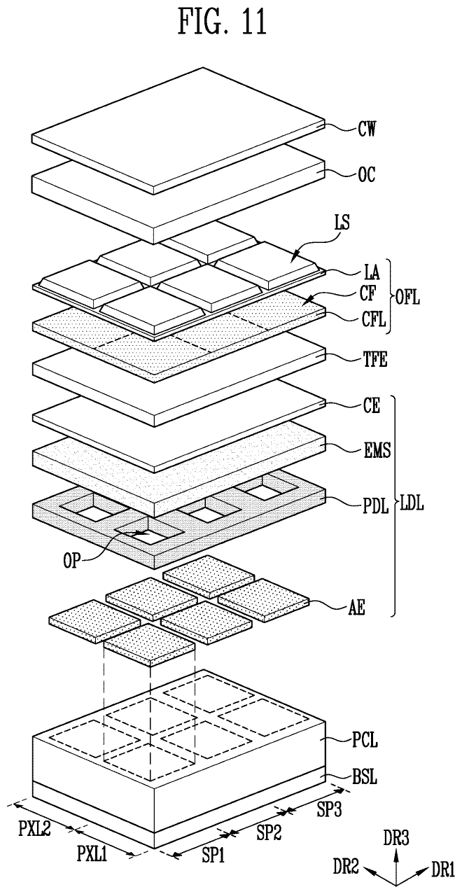

FIG. 11 is an exploded perspective view illustrating a part of the display panel of FIG. 4. In FIG. 11, a part of the display panel DP corresponding to two pixels PXL1 and PXL2 among the pixels PXL of FIG. 4 is schematically illustrated for convenience of illustration and description. The other parts of the display panel DP corresponding to the other pixels may be configured similarly.

Referring to FIG. 11, in an embodiment, each of the first and second pixels PXL1 and PXL2 may include first, second, and third sub-pixels SP1, SP2, and SP3. However, embodiments are not limited thereto. In another embodiment, for example, each of the first and second pixels PXL1 and PXL2 may include four sub-pixels or two sub-pixels.

FIG. 11 illustrates an embodiment where the first, second, and third sub-pixels SP1, SP2, and SP3 each have a rectangular shape and have a same size when viewed in a third direction DR3 intersecting the first direction DR1 and the second direction DR2. However, embodiments are not limited thereto. The first, second, and third sub-pixels SP1, SP2, and SP3 may be modified to have various shapes.

The display panel DP may include the base layer BSL, a pixel circuit layer PCL, a light emitting element layer LDL, an encapsulation layer TFE, an optical function layer OFL, an overcoat layer OC, and a cover window CW.

In an embodiment, the base layer BSL may include a silicon wafer substrate formed through a semiconductor process. The base layer BSL may include a semiconductor material suitable for forming circuit elements. In an embodiment, for example, the semiconductor material may include silicon, germanium, and/or silicon-germanium. The base layer BSL may also be provided from a bulk wafer, an epitaxial layer, a silicon on insulator (SOI) layer, or a semiconductor on insulator (SeOI) layer. In another embodiment, the base layer BSL may include a glass substrate. In another embodiment, the base layer BSL may include a polyimide (PI) substrate.

The pixel circuit layer PCL is disposed on the base layer BSL. The base layer BSL and/or the pixel circuit layer PCL may include insulating layers and conductive patterns between the insulating layers. The conductive patterns of the pixel circuit layer PCL may function as at least a part of circuit elements, wires, or the like. The conductive patterns may include copper, but embodiments are not limited thereto.

The circuit elements may include the sub-pixel circuit SPC (see FIG. 2) of each of the first, second, and third sub-pixels SP1, SP2, and SP3. The sub-pixel circuit SPC may include transistors and one or more capacitors. The transistor may each include a semiconductor portion including a source region, a drain region, and a channel region, and a gate electrode overlapped on the semiconductor portion. In an embodiment, where the base layer BSL is provided as a silicon substrate, the semiconductor portion may be included in the base layer BSL, and the gate electrode may be included in the pixel circuit layer PCL as a conductive pattern of the pixel circuit layer PCL. In an embodiment, where the base layer BSL is provided as a glass substrate or a PI substrate, the semiconductor portion and the gate electrode may be included in the pixel circuit layer PCL. Each capacitor may include electrodes separated from each other. In an embodiment, for example, each capacitor may include electrodes separated from each other on a plane defined by the first direction DR1 and the second direction DR2. In an embodiment, for example, each capacitor may include electrodes separated from each other in the third direction DR3 with an insulating layer therebetween.

Wires of the pixel circuit layer PCL may include signal lines, such as a gate line, a light emission control line, and a data line, connected to each of the first, second, and third sub-pixels SP1, SP2, and SP3. The wires may further include a wire connected to the first power voltage node VDDN of FIG. 2. In addition, the wires may further include a wire connected to the second power voltage node VSSN of FIG. 2.

The light emitting element layer LDL may include anode electrodes AE (or a first electrode), a pixel definition layer PDL, a light emitting structure EMS, and a cathode electrode CE (or a second electrode).

The anode electrodes AE may be disposed on the pixel circuit layer PCL. The anode electrodes AE may be in contact with circuit elements of the pixel circuit layer PCL. The anode electrodes AE may each include an opaque conductive material capable of reflecting light, but embodiments are not limited thereto.

The pixel definition layer PDL is disposed on the anode electrodes AE. The pixel definition layer PDL may be provided with openings OP exposing a part of each of the anode electrodes AE. Light emitting regions corresponding to the first to third sub-pixels SP1 to SP3 may be defined by the openings OP of the pixel definition layer PDL. Alternatively, it can be understood that the light emitting regions corresponding to the first to third sub-pixels SP1 to SP3 are defined by the anode electrodes AE. In a region adjacent to a boundary of neighboring sub-pixels, the pixel definition layer PDL may include separators that cause discontinuity in the light emitting structure EMS. In such an embodiment, it can be understood that light emitting regions corresponding to the first to third sub-pixels SP1 to SP3 are defined by the separators of the pixel definition layer PDL.

In an embodiment, the pixel definition layer PDL may include an inorganic material. In such an embodiment, the pixel definition layer PDL may include a plurality of stacked inorganic layers. In an embodiment, for example, the pixel definition layer PDL may include silicon oxide SiOₓ and silicon nitride SiNₓ. In another embodiment, the pixel definition layer PDL may include an organic material. However, the material of the pixel definition layer PDL is not limited thereto.

The light emitting structure EMS may be disposed on the anode electrodes AE exposed by the openings OP of the pixel definition layer PDL. The light emitting structure EMS may include a light emitting layer configured to generate light, an electron transfer layer configured to transfer electrons, a hole transfer layer configured to transfer holes, or the like.

In an embodiment, the light emitting structure EMS may be disposed entirely on the pixel definition layer PDL while filling the openings OP of the pixel definition layer PDL. In such an embodiment, the light emitting structure EMS may extend over the first to third sub-pixels SP1 to SP3. In such an embodiment, at least some of layers in the light emitting structure EMS may be separated or bent at boundaries between the first to third sub-pixels SP1 to SP3. However, embodiments are not limited thereto. In an embodiment, for example, portions of the light emitting structure EMS corresponding to the first to third sub-pixels SP1 to SP3 may be separated from each other, and each of the portions may be disposed in the openings OP of the pixel definition layer PDL.

The cathode electrode CE may be disposed on the light emitting structure EMS. In an embodiment, the cathode electrode CE may extend across the first to third sub-pixels SP1 to SP3. In such an embodiment, the cathode electrode CE may be provided as a common electrode for the first to third sub-pixels SP1 to SP3.

The cathode electrode CE may be a thin metal layer having a thickness that is sufficient to transmit light, which is emitted from the light emitting structure EMS, therethrough. The cathode electrode CE may include or be formed of a metal material or a transparent conductive material to have a relatively thin thickness. In an embodiment, the cathode electrode CE may include at least one selected from various transparent conductive materials, such as indium tin oxide, indium zinc oxide, indium tin zinc oxide, aluminum zinc oxide, gallium zinc oxide, zinc tin oxide, and gallium tin oxide. In another embodiment, the cathode electrode CE may include at least one selected from silver (Ag), magnesium (Mg), and a mixture thereof. However, the material of the cathode electrode CE is not limited thereto.

It may be understood that any one of the anode electrodes AE, a portion constitute one light emitting structure EMS overlapping the any one of the anode electrodes AE, and a portion of the cathode electrode CE overlapping the portion constitute the one light emitting element LD (see FIG. 2). In such an embodiment, each of the light emitting elements of the first to third sub-pixels SP1 to SP3 may include one anode electrode, a portion of the light emitting structure EMS overlapping the one anode electrode, and a portion of a cathode electrode CE overlapping the portion. In each of the first to third sub-pixels SP1 to SP3, holes injected from the anode electrodes AE and electrons injected from the cathode electrode CE are transferred into a light emitting layer of the light emitting structure EMS to form excitons, and when the excitons are shifted from an excited state to a ground state, light may be generated. The brightness of light may be determined according to the amount of a current flowing through a light emitting layer. A wavelength range of the generated light may be determined based on a configuration of the light emitting layer.

The encapsulation layer TFE is disposed on the cathode electrode CE. The encapsulation layer TFE may cover the light emitting element layer LDL and/or the pixel circuit layer PCL. The encapsulation layer TFE may be configured to prevent oxygen and/or moisture from penetrating into the light emitting element layer LDL. In an embodiment, the encapsulation layer TFE may include a structure in which one or more inorganic films and one or more organic films are alternately stacked. In an embodiment, for example, the inorganic film may include silicon nitride, silicon oxide, or silicon oxynitride (SiOₓN_{y}). In an embodiment, for example, the organic film may include an organic insulating material, such as an acrylic resin, an epoxy resin, a phenol resin, a polyamide resin, a polyimide resin, an unsaturated polyester resin, a polyphenyleneether resin, a polyphenylenesulfide resin, or benzocyclobutene (BCB). However, the materials of the organic film and the inorganic film of the encapsulation layer TFE are not limited thereto.

In order to improve an encapsulation efficiency of the encapsulation layer TFE, the encapsulation layer TFE may further include a thin film including aluminum oxide (AIOₓ). The thin film including aluminum oxide may be placed on an upper surface of the encapsulation layer TFE facing the optical function layer OFL and/or on a lower surface of the encapsulation layer TFE facing the light emitting device layer LDL.

The thin film including aluminum oxide may be formed by using an atomic layer deposition (ALD) method. However, embodiments are not limited thereto. The encapsulation layer TFE may further include a thin film formed of at least one selected from various materials suitable for increasing the encapsulation efficiency.

The optical function layer OFL is disposed on the encapsulation layer TFE. The optical function layer OFL may include a color filter layer CFL and a lens array LA.

The color filter layer CFL is disposed between the encapsulation layer TFE and the lens array LA. The color filter layer CFL is configured to filter the light emitted from the light emitting structure EMS to selectively output light in a wavelength range or of a color corresponding to each sub-pixel. The color filter layer CFL may include color filters CF respectively corresponding to the first to third sub-pixels SP1 to SP3, and each of the color filters CF may transmit therethrough light in a wavelength range corresponding to a corresponding sub-pixel. In an embodiment, for example, a color filter corresponding to the first sub-pixel SP1 may transmit red color light therethrough, a color filter corresponding to the second sub-pixel SP2 may transmit green color light therethrough, and a color filter corresponding to the third sub-pixel SP3 may transmit blue color light therethrough. At least some of the color filters CF may be omitted depending on the light emitted from the light emitting structure EMS of each sub-pixel.

The lens array LA is disposed on the color filter layer CFL. The lens array LA may include lenses LS respectively corresponding to the first to third sub-pixels SP1 to SP3. Each of the lenses LS may increase light emission efficiency by outputting the light emitted from the light emitting structure EMS to an intended path. The lens array LA may have a relatively high refractive index. For example, the lens array LA may have a higher refractive index than the overcoat layer OC. In an embodiment, the lenses LS may each include an organic material. In an embodiment, the lenses LS may each include an acrylic material. However, the materials of the lenses LS are not limited thereto.

In an embodiment, at least some of the color filters CF of the color filter layer CFL and at least some of the lenses LS of the lens array LA may be shifted in a direction parallel to a plane defined by the first and second directions DR1 and DR2, with respect to the openings OP of the pixel definition layer PDL. In an embodiment, for example, in a central region of the display region DA, the center of the color filter and the center of the lens may be aligned or overlapped with the center of the opening OP of the corresponding pixel definition layer PDL when viewed in the third direction DR3. In an embodiment, for example, in the central region of the display region DA, the opening OP of the pixel definition layer PDL may completely overlap a corresponding color filter of the color filter layer CFL and a corresponding lens of the lens array LA. In a region adjacent to the non-display region NDA of the display region DA, the center of the color filter and the center of the lens may be shifted in a plane direction from the center of the opening OP of the corresponding pixel definition layer PDL when viewed in the third direction DR3. In an embodiment, for example, in the region adjacent to the non-display region NDA of the display region DA, the opening OP of the pixel definition layer PDL may partially overlap a corresponding color filter of the color filter layer CFL and a corresponding lens of the lens array LA. Accordingly, in the center of the display region DA, the light emitted from the light emitting structure EMS may be efficiently output in a normal direction of a display surface. In the periphery of the display region DA, the light emitted from the light emitting structure EMS may be efficiently output in a direction inclined by a predetermined angle with respect to the normal direction of the display surface.

The overcoat layer OC may be disposed on the lens array LA. The overcoat layer OC may cover the optical function layer OFL, the encapsulation layer TFE, the light emitting structure EMS, and/or the pixel circuit layer PCL. The overcoat layer OC may include various materials suitable for protecting layers under the overcoat layer OC from foreign substances such as dust, moisture, or the like. In an embodiment, for example, the overcoat layer OC may include at least one of an inorganic insulating film and an organic insulating film. In an embodiment, for example, the overcoat layer OC may include epoxy, but embodiments are not limited thereto. The overcoat layer OC may have a lower refractive index than the lens array LA.

The cover window CW may be disposed on the overcoat layer OC.

The cover window CW is configured to protect layers under the cover window CW. The cover window CW may have a higher refractive index than the overcoat layer OC. The cover window CW may include glass, but embodiments are not limited thereto. In an embodiment, for example, the cover window CW may be an encapsulation glass configured to protect components disposed thereunder. In another embodiment, the cover window CW may be omitted.

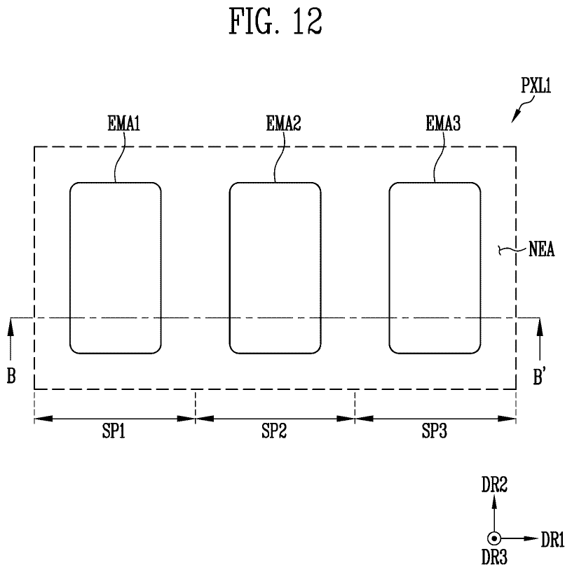

FIG. 12 is a plan view illustrating an embodiment of one of the pixels of FIG. 11. In FIG. 12, the first pixel PXL1 among the first and second pixels PXL1 and PXL2 of FIG. 11 is schematically illustrated for convenience of illustration and description. The other pixels may also be configured similarly to the first pixel PXL1.

Referring to FIGS. 11 and 12, an embodiment of the first pixel PXL1 may include first, second, and third sub-pixels SP1, SP2, and SP3 arranged in the first direction DR1.

The first sub-pixel SP1 may include a first light emitting region EMA1 and a non-light emitting region NEA around the first light emitting region EMA1. The second sub-pixel SP2 may include a second light emitting region EMA2 and a non-light emitting region NEA around the second light emitting region EMA2. The third sub-pixel SP3 may include a third light emitting region EMA3 and a non-light emitting region NEA around the third light emitting region EMA3.

The first light emitting region EMA1 may be a region where light is emitted from a portion of the light emitting structure EMS (see FIG. 11) corresponding to the first sub-pixel SP1. The second light emitting region EMA2 may be a region where light is emitted from a portion of a light emitting structure EMS corresponding to the second sub-pixel SP2. The third light emitting region EMA3 may be a region where light is emitted from a portion of a light emitting structure EMS corresponding to the third sub-pixel SP3.

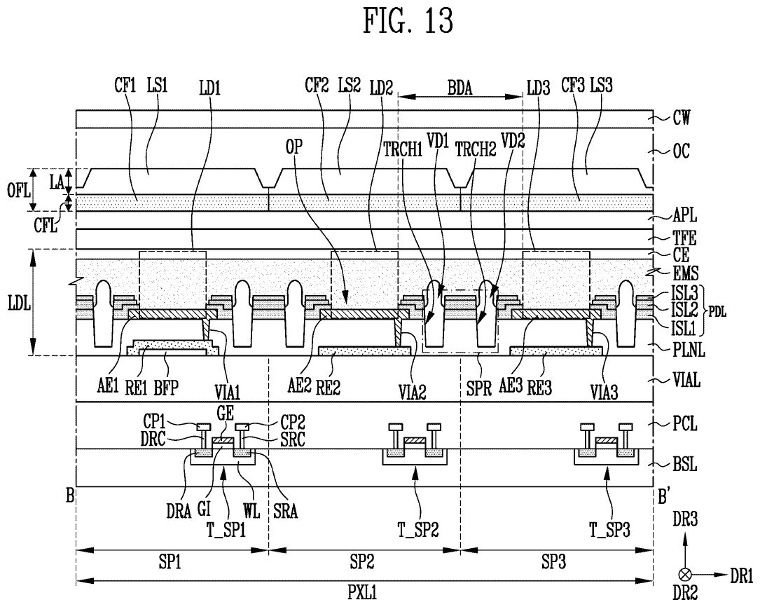

FIG. 13 is a cross-sectional view taken along line B-B′ of FIG. 12, according to an embodiment of the disclosure.

Referring to FIG. 13, in an embodiment, the base layer BSL and the pixel circuit layer PCL disposed on the base layer BSL are provided.

The base layer BSL may include a silicon wafer substrate formed through a semiconductor process. In an embodiment, for example, the base layer BSL may include silicon, germanium, and/or silicon-germanium.

The pixel circuit layer PCL is disposed on the base layer BSL. The base layer BSL and the pixel circuit layer PCL may include respective circuit elements of the first to third sub-pixels SP1 to SP3. In an embodiment, for example, the base layer BSL and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of transistors included in the sub-pixel circuit SPC (see FIG. 2) of the first sub-pixel SP1, the transistor T_SP2 of the second sub-pixel SP2 may be one of transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. For convenience of illustration and description, FIG. 13 illustrates one of the transistors of each sub-pixel, and other circuit elements are omitted.

The transistor T_SP1 of the first sub-pixel SP1 may include a source region SRA, a drain region DRA, and a gate electrode GE.

The source region SRA and the drain region DRA may be disposed in the base layer BSL. A well WL formed through an ion implantation process is disposed in the base layer BSL, and the source region SRA and the drain region DRA may be separated from each other in the well WL. A region between the source region SRA and the drain region DRA in the well WL may be defined as a channel region. The gate electrode GE overlaps a channel region between the source region SRA and the drain region DRA and may be disposed in the pixel circuit layer PCL. The gate electrode GE may be separated from the well WL or the channel region by an insulating material, such as a gate insulating layer GI. The gate electrode GE may include a conductive material.

A plurality of layers included in the pixel circuit layer PCL may include conductive patterns disposed between insulating layers, and the conductive patterns may include a first conductive pattern CP1 and a second conductive pattern CP2. The first conductive pattern CP1 may be electrically connected to the drain region DRA through a drain connection portion DRC disposed through one or more insulating layers. The second conductive pattern CP2 may be electrically connected to the source region SRA through a source connection portion SRC disposed through one or more insulating layers.

As the gate electrode GE, the first conductive pattern CP1, and the second conductive pattern CP2 are connected to other circuit elements and/or wires, the transistor T_SP1 of the first sub-pixel SP1 may be provided as one of the transistors of the first sub-pixel SP1.

The transistor T_SP2 of the second sub-pixel SP2 and the transistor T_SP3 of the third sub-pixel SP3 may be similar to the transistor T_SP1 of the first sub-pixel SP1.

In such an embodiment, the base layer BSL and the pixel circuit layer PCL GE may include circuit elements of the first to third sub-pixels SP1 to SP3.

A via layer VIAL is disposed on the pixel circuit layer PCL. The via layer VIAL may cover the pixel circuit layer PCL and may have an entirely flat surface. The via layer VIAL is configured to flatten step differences (or provides a flat upper surface) on the pixel circuit layer PCL. The via layer VIAL may include at least one selected from silicon oxide (SiOₓ), silicon nitride (SiNₓ), and silicon carbon nitride (SiCN), but embodiments are not limited thereto.

A light emitting element layer LDL is disposed on the via layer VIAL. The light emitting element layer LDL may include first to third reflective electrodes RE1 to RE3, a planarization layer PLNL, first to third anode electrodes AE1 to AE3, a pixel definition layer PDL, a light emitting structure EMS, and a cathode electrode CE.

In an embodiment, the first to third reflective electrodes RE1 to RE3 are disposed on the via layer VIAL to correspond to first to third sub-pixels SP1 to SP3, respectively. Each of the first to third reflective electrodes RE1 to RE3 may be in contact with a circuit element disposed on the pixel circuit layer PCL through a via disposed through the via layer VIAL.

The first to third reflective electrodes RE1 to RE3 may function as full mirrors that reflect the light emitted from the light emitting structure EMS toward a display surface (or a cover window CW). The first to third reflective electrodes RE1 to RE3 may include metal materials suitable for reflecting light. The first to third reflective electrodes RE1 to RE3 may each include at least one selected from aluminum (AI), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom, but embodiments are not limited thereto.

In an embodiment, connection electrodes may be respectively disposed under the first to third reflective electrodes RE1 to RE3. The connection electrodes may improve electrical connection characteristics between the corresponding reflective electrode and circuit elements of the pixel circuit layer PCL. The connection electrodes may each have a multilayer structure. The multilayer structure may include titanium (Ti), titanium nitride (TiN), tantalum nitride (TaN), or so on, but embodiments are not limited thereto. In an embodiment, the corresponding reflective electrode may be provided between the multilayers of the connection electrode.

A buffer pattern BFP may be disposed under at least one of the first to third reflective electrodes RE1 to RE3. The buffer pattern BFP may include an inorganic material, such as silicon carbon nitride, but embodiments are not limited thereto. By disposing the buffer pattern BFP, a height of a corresponding reflective electrode in the third direction DR3 may be adjusted. In an embodiment, for example, the buffer pattern BFP may be disposed between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. In an embodiment, for example, the first to third reflective electrodes RE1 to RE3 and the cathode electrode CE may provide a resonance structure in a corresponding sub-pixel. The light emitted from a light emitting layer of the light emitting structure EMS may be amplified by reciprocating between a corresponding reflective electrode and the cathode electrode CE, and the amplified light may be output through the cathode electrode CE. In such an embodiment, a distance between each reflective electrode and the cathode electrode CE may be understood as a resonance distance for the light emitted from the light emitting layer of the corresponding light emitting structure EMS.

The first sub-pixel SP1 may have a shorter resonance distance than other sub-pixels by the buffer pattern BFP. The resonance distance adjusted in this way may cause the light in a specific wavelength range (for example, a red color) to be effectively and efficiently amplified. Accordingly, the first sub-pixel SP1 may effectively and efficiently output the light in a corresponding wavelength range.

Although FIG. 13 illustrates an embodiment where the buffer pattern BFP is provided to the first sub-pixel SP1 and is not provided to the second and third sub-pixels SP2 and SP3, embodiments are not limited thereto. In another embodiment, the buffer pattern BFP may be further provided to at least one selected from the second and third sub-pixels SP2 and SP3 to adjust a resonance distance of at least one of the second and third sub-pixels SP2 and SP3. In an embodiment, for example, the first to third sub-pixels SP1 to SP3 may respectively correspond to red, green, and blue, a distance between the first reflective electrode RE1 and the cathode electrode CE may be shorter than a distance between the second reflective electrode RE2 and the cathode electrode CE, and a distance between the second reflective electrode RE2 and the cathode electrode CE may be shorter than a distance between the third reflective electrode RE3 and the cathode electrode CE.

In an embodiment, a planarization layer PLNL may be disposed on the via layer VIAL and the first to third reflective electrodes RE1 to RE3 to planarize a step difference between the first to third reflective electrodes RE1 to RE3. The planarization layer PLNL may cover the first to third reflective electrodes RE1 to RE3 and the via layer VIAL as a whole and may have a planar surface. In an embodiment, the planarization layer PLNL may be omitted.

In an embodiment, first to third anode electrodes AE1 to AE3 are disposed on the planarization layer PLNL to respectively overlap the first to third reflective electrodes RE1 to RE3. The first to third anode electrodes AE1 to AE3 may have shapes similar to those of the first to third light emitting regions EMA1 to EMA3 of FIG. 6 when viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 disposed through the planarization layer PLNL. The second anode electrode AE2 may be connected to the second reflective electrode RE2 through a second via VIA2 disposed through the planarization layer PLNL. The third anode electrode AE3 may be connected to the third reflective electrode RE3 through a third via VIA3 disposed through the planarization layer PLNL.

In an embodiment, the first to third anode electrodes AE1 to AE3 may each include at least one selected from transparent conductive materials, such as indium tin oxide (ITO), indium zinc oxide (IZO), zinc oxide (ZnOₓ), indium gallium zinc oxide (IGZO), and indium tin zinc oxide (ITZO). However, the materials of the first to third anode electrodes AE1 to AE3 are not limited thereto. In an embodiment, for example, the first to third anode electrodes AE1 to AE3 may each include titanium nitride (TiN).

A pixel definition layer PDL is partially disposed on the first to third anode electrodes AE1 to AE3 and may be disposed on the planarization layer PLNL. The pixel definition layer PDL is provided with openings OP respectively and partially exposing the first to third anode electrodes AE1 to AE3. A region overlapping the pixel definition layer PDL may be understood as a boundary region BDA between neighboring sub-pixels.

In an embodiment, the pixel definition layer PDL may include a plurality of inorganic insulating layers. Each of the plurality of inorganic insulating layers may include at least one selected from silicon oxide (SiOₓ) and silicon nitride (SiNₓ). In an embodiment, for example, the pixel definition layer PDL may include a first inorganic insulating layer ISL1, a second inorganic insulating layer ISL2, and a third inorganic insulating layer ISL3 that are sequentially stacked. The first to third inorganic insulating layers ISL1 to ISL3 may each include silicon nitride or silicon oxide, but embodiments are not limited thereto. The first to third inorganic insulating layers ISL1 to ISL3 may each have a step-shaped cross-section in each of regions adjacent to the openings OP.

The pixel definition layer PDL may include a separator SPR in the boundary region BDA between neighboring sub-pixels. In an embodiment, the separator SPR may be provided in each of the boundary regions between the sub-pixels SP of FIG. 4.

The separator SPR may cause a discontinuous portion to be formed within the light emitting structure EMS in the boundary region BDA. In an embodiment, for example, the light emitting structure EMS may be disconnected or bent in the boundary region BDA by the separator SPR. Therefore, the first to third light emitting regions EMA1 to EMA3 of FIG. 12 respectively corresponding to the first to third sub-pixels SP1 to SP3 may be defined by the separator SPR of the pixel definition layer PDL.

The separator SPR may be provided in or on the pixel definition layer PDL. The pixel definition layer PDL may include one or more trenches TRCH1 and TRCH2 in the boundary region BDA as the separator SPR. In an embodiment, as illustrated in FIG. 13, the one or more trenches TRCH1 and TRCH2 may penetrate through the pixel definition layer PDL and partially penetrate the planarization layer PLNL. In another embodiment, the one or more trenches TRCH1 and TRCH2 may penetrate through the pixel definition layer PDL and the planarization layer PLNL and partially penetrate the via layer VIAL. In another embodiment, the one or more trenches TRCH1 and TRCH2 may at least partially penetrate through the planarization layer PLNL and/or the via layer VIAL, and a part of the pixel definition layer PDL may be disposed in the one or more trenches TRCH1 and TRCH2.

FIG. 13 illustrates an embodiment where two trenches TRCH1 and TRCH2 are provided in the boundary region BDA. However, embodiments are not limited thereto. In another embodiment, for example, the pixel definition layer PDL may include a single trench in the boundary region BDA. Alternatively, the pixel definition layer PDL may include three or more trenches in the boundary region BDA.

Due to first and second trenches TRCH1 and TRCH2, discontinuous portions, such as a first void VD1 and a second void VD2, may be formed in the light emitting structure EMS in the boundary region (BDA). Some of the plurality of layers stacked in the light emitting structure EMS may be disconnected or bent by the first and second voids VD1 and VD2. In an embodiment, for example, at least one charge generation layer and at least one hole injection layer included in the light emitting structure EMS may be respectively disconnected in the first and second voids VD1 and VD2. In this way, portions of the light emitting structure EMS included in the first to third sub-pixels SP1 to SP3 may be at least partially separated by the first and second trenches TRCH1 and TRCH2.

Depending on shapes of the first and second trenches TRCH1 and TRCH2, the discontinuous portions formed in the light emitting structure EMS may be variously changed.

In an embodiment, the light emitting structure EMS may be formed through processes, such as vacuum deposition and inkjet printing. In such an embodiment, materials identical to the light emitting structure EMS may be located on bottom surfaces adjacent to the via layer VIAL among the first and second trenches TRCH1 and TRCH2.

In order for the light emitting structure EMS to further include a discontinuous portion adjacent to the boundary region BDA, the pixel definition layer PDL may include an additional separator. In an embodiment, the third inorganic insulating layer ISL3 in the uppermost portion among the first to third inorganic insulating layers ISL1 to ISL3 of the pixel definition layer PDL may have a greater width than a width of the second inorganic insulating layer ISL2 disposed directly below the third inorganic insulating layer ISL3. In an embodiment, for example, the pixel definition layer PDL may have a cross-section having a “T” shape or an “I” shape in the boundary region BDA. Depending on shapes of the pixel definition layer PDL, a plurality of layers included in the light emitting structure EMS may be at least partially disconnected or bent in the boundary region BDA or in a region that is adjacent to the boundary region BDA.

The light emitting structure EMS may be disposed on the anode electrodes AE exposed by the opening OP of the pixel definition layer PDL. The light emitting structure EMS may fill the openings OP of the pixel definition layer PDL and may be disposed entirely over the first to third sub-pixels SP1 to SP3. As described above, the light emitting structure EMS may be at least partially disconnected or bent in the boundary region BDA by the separator SPR Accordingly, during an operation of the display panel DP, a current flowing from each of the first to third sub-pixels SP1 to SP3 to the neighboring sub-pixel through the layers included in the light emitting structure EMS may be reduced. Therefore, the first to third light emitting elements LD1 to LD3 may operate with relatively high reliability.

The cathode electrode CE may be disposed on the light emitting structure EMS. The cathode electrode CE may be provided in common to the first to third sub-pixels SP1 to SP3. The cathode electrode CE may function as a half mirror that partially transmits light emitted from the light emitting structure EMS therethrough and partially reflects the light.

The first anode electrode AE1, a portion of the light emitting structure EMS overlapping the first anode electrode AE1, and a portion of the cathode electrode CE overlapping the first anode electrode AE1 may constitute the first light emitting element LD1. The second anode electrode AE2, a portion of the light emitting structure EMS overlapping the second anode electrode AE2, and a portion of the cathode electrode CE overlapping the second anode electrode AE2 may constitute the second light emitting element LD2. The third anode electrode AE3, a portion of the light emitting structure EMS overlapping the third anode electrode AE3, and a portion of the cathode electrode CE overlapping the third anode electrode AE3 may constitute the third light emitting element LD3.

An encapsulation layer TFE is disposed on the cathode electrode CE. The encapsulation layer TFE may effectively prevent oxygen, moisture, and/or so on from penetrating into the light emitting element layer LDL.

The optical function layer OFL is disposed on the encapsulation layer TFE. In an embodiment, the optical function layer OFL may be attached to the encapsulation layer TFE through an adhesive layer APL. In an embodiment, for example, the optical function layer OFL may be formed separately and attached to the encapsulation layer TFE through the adhesive layer APL. The adhesive layer APL may further perform a function of protecting lower layers including the encapsulation layer TFE.

The optical function layer OFL may include a color filter layer CFL and a lens array LA. The color filter layer CFL may include first to third color filters (CF1 to CF3) respectively corresponding to the first to third sub-pixels SP1 to SP3. The first to third color filters CF1 to CF3 may transmit light in different wavelength ranges therethrough. In an embodiment, for example, the first to third color filters CF1 to CF3 may respectively transmit red light, green light, and blue light therethrough.

In an embodiment, the first to third color filters CF1 to CF3 may partially overlap each other in the boundary region BDA. In other embodiments, the first to third color filters CF1 to CF3 may be separated from each other, and a black matrix may be provided between the first to third color filters CF1 to CF3.

The lens array LA is disposed on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light emitting elements LD1 to LD3 to intended paths, thereby increase light emission efficiency.

The overcoat layer OC may be disposed on the lens array LA. The overcoat layer OC is configured to protect layers under the overcoat layer OC from foreign substances, such as dust, moisture, or the like. The cover window CW may be disposed on the overcoat layer OC.

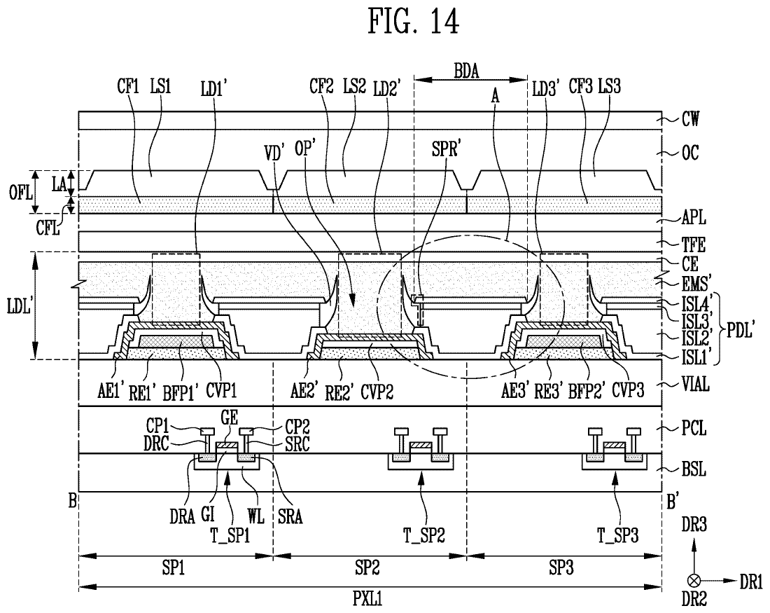

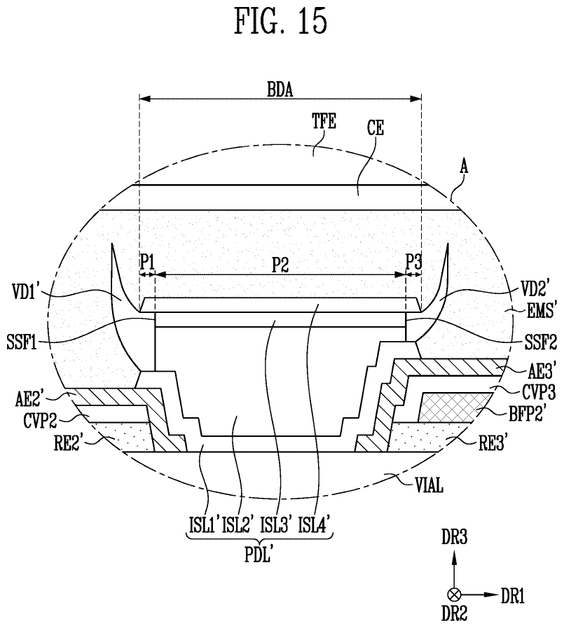

FIG. 14 is a cross-sectional view taken along line B-B′ of FIG. 12, according to another embodiment of the disclosure. FIG. 15 is an enlarged view illustrating a region A of FIG. 14.

Referring to FIG. 14, in an embodiment, a pixel circuit layer PCL and a via layer VIAL are disposed on a base layer BSL. The base layer BSL, the pixel circuit layer PCL, and the via layer VIAL of FIG. 14 are respectively similarly to the base layer BSL, the pixel circuit layer PCL, and the via layer VIAL of FIG. 13. In FIG. 14, the same or like reference characters are used to refer to the same or like elements as those described above, and any repetitive detailed descriptions thereof may hereinafter be omitted or simplified.

A light emitting element layer LDL′ is disposed on the via layer VIAL. The light emitting element layer LDL′ may include first to third reflective electrodes RE1′ to RE3′, first and second buffer patterns BFP1′ and BFP2′, first to third cover patterns CVP1 to CVP3, first to third anode electrodes AE1′ to AE3′, a pixel definition layer PDL′, a light emitting structure EMS′, and a cathode electrode CE.

In an embodiment, the first to third reflective electrodes RE1′ to RE3′ are disposed on the via layer VIAL to correspond to first to third sub-pixels SP1 to SP3, respectively. Each of the first to third reflective electrodes RE1′ to RE3′ may be respectively in contact with circuit elements disposed on the pixel circuit layer PCL through vias penetrating the via layer VIAL.

The first to third reflective electrodes RE1′ to RE3′ are configured to reflect the light emitted from the light emitting structure EMS' toward a display surface (or, a cover window CW). The first to third reflective electrodes RE1′ to RE3′ may each include a metal material that is suitable for reflecting the light. The first to third reflective electrodes RE1′ to RE3′ may each include at least one selected from aluminum (AI), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom, but embodiments are not limited thereto.

In the embodiment, a connection electrode may be further provided between each of the first to third reflective electrodes RE1′ to RE3′ and the via layer VIAL. The connection electrode may improve electrical connection characteristics between a corresponding reflective electrode and each of the circuit elements of the pixel circuit layer PCL. The connection electrode may have a multilayer structure. The multilayer structure may include titanium (Ti), aluminum (AI), titanium nitride (TiN), tantalum nitride (TaN), or the like, but embodiments are not limited thereto. In the embodiment, a corresponding reflective electrode may also be located between the multilayers of the connection electrode.

A buffer pattern may be disposed on at least one of the first to third reflective electrodes RE1′ to RE3′. In an embodiment, the first and second buffer patterns BFP1′ and BFP2′ may be respectively disposed on the first and third reflective electrodes RE1′ and RE3′. By the first and second buffer patterns BFP1′ and BFP2′, heights of the first and third anode electrodes AE1′ and AE3′ in the third direction DR3 may be adjusted. The first and second buffer patterns BFP1′ and BFP2′ may include at least one selected from inorganic materials, such as silicon oxide (SiOₓ) and silicon nitride (SiNₓ), but embodiments are not limited thereto.

The first to third cover patterns CVP1 to CVP3 may be respectively disposed on the first to third reflective electrodes RE1′ to RE3′. In the first sub-pixel SP1, the first cover pattern CVP1 is disposed on the first reflective electrode RE1′ and the first buffer pattern BFP1′. In the second sub-pixel SP2, the second cover pattern CVP2 is disposed on the second reflective electrode RE2′. In the third sub-pixel SP3, the third cover pattern CVP3 is disposed on the third reflective electrode RE3′ and the second buffer pattern BFP2′. The first to third cover patterns CVP1 to CVP3 may be formed after the first and second buffer patterns BFP1′ and BFP2′ are formed during a manufacturing process of the first to third cover patterns CVP1 to CVP3. The first to third cover patterns CVP1 to CVP3 may include the same material as the first and second buffer patterns BFP1′ and BFP2′. In an embodiment, for example, the first to third cover patterns CVP1 to CVP3 may include at least one selected from inorganic materials, such as silicon oxide (SiOₓ) and silicon nitride (SiNₓ), but embodiments are not limited thereto.

The first to third anode electrodes AE1′ to AE3′ are respectively disposed on the first to third cover patterns CVP1 to CVP3. In an embodiment, the first anode electrode AE1′ may cover the first cover pattern CVP1, the first buffer pattern BFP1′, and the first reflective electrode RE1′. The second anode electrode AE2′ may cover the second cover pattern CVP2 and the second reflective electrode RE2′. The third anode electrode AE3′ may cover the third cover pattern CVP3, the second buffer pattern BFP2′, and the third reflective electrode RE3′.

The first to third anode electrodes AE1′ to AE3′ may be respectively and electrically connected to the first to third reflective electrodes RE1′ to RE3′. In an embodiment, for example, each anode electrode may be connected to an end (or an edge) of a corresponding reflective electrode. However, embodiments are not limited thereto. In order to improve electrical connection characteristics between an anode electrode and a reflective electrode, the anode electrode may be connected to the reflective electrode in various ways.

In the embodiment, the first to third anode electrodes AE1′ to AE3′ may include at least one selected from transparent conductive materials, such as indium tin oxide (ITO), indium zinc oxide (IZO), zinc oxide (ZnOₓ), indium gallium zinc oxide (IGZO), and indium tin zinc oxide (ITZO). However, the materials of the first to third anode electrodes AE1′ to AE3′ are not limited thereto. In an embodiment, for example, the first to third anode electrodes AE1′ to AE3′ may each include titanium nitride.

The first to third anode electrodes AE1′ to AE3′ may have shapes similar to those of the first to third light emitting regions EMA1 to EMA3 of FIG. 12 when viewed in the third direction DR3.

The first to third anode electrodes AE1′ to AE3′ and the cathode electrode CE may partially reflect incident light. The light emitted from a light emitting layer of the light emitting structure EMS' may be amplified by reciprocating between the anode electrode and the cathode electrode CE and output through the cathode electrode CE. In an embodiment, for example, each anode electrode and the cathode electrode CE may provide a resonance structure in a corresponding sub-pixel. In such an embodiment, a distance between each anode electrode and the cathode electrode CE may be understood as a resonance distance to the light emitted from a light emitting layer of the corresponding light emitting structure EMS′.

The first to third sub-pixels SP1 to SP3 may respectively correspond to red, green, and blue. In an embodiment, heights of the first and third anode electrodes AE1′ and AE3′ in the third direction DR3 may be higher than a height of the second anode electrode AE2′ by the first and second buffer patterns BFP1′ and BFP2′). Accordingly, the first and third sub-pixels SP1 and SP3 may have shorter resonance distances than a resonance distance of the second sub-pixel SP2 by the first and second buffer patterns BFP1′ and BFP2′. In such an embodiment, the resonance distance of each sub-pixel may be adjusted such that light of a wavelength range of a corresponding color is effectively and efficiently amplified.

Although FIG. 14 illustrate an embodiment where the first and second buffer patterns BFP1′ and BFP2′ are respectively disposed below the first and third anode electrodes AE1′ and AE3′, embodiments are not limited thereto. In another embodiment, for example, one of the first and second buffer patterns BFP1′ and BFP2′ may be omitted. In another embodiment, for example, both the first and second buffer patterns BFP1′ and BFP2′ may be omitted. In such an embodiment, resonance distances between the respective anode electrodes and the cathode electrode CE may be the same as each other. In another embodiment, for example, a buffer pattern may be disposed under each of the first to third anode electrodes AE1′ to AE3′. In such an embodiment, buffer patterns disposed under the respective anode electrodes may have different thicknesses, and accordingly, resonance distances between the respective anode electrodes and the cathode electrode CE may be different from each other. In such embodiments, by providing a buffer pattern for adjusting a height of the anode electrode under at least one selected from the first to third anode electrodes AE1′ to AE3′, the resonance distance in each sub-pixel may be optimized.

The pixel definition layer PDL′ is disposed on a part of each of the first to third anode electrodes AE1′ to AE3′ and the via layer VIAL. The pixel definition layer PDL′ has openings OP′ that partially expose the first to third anode electrodes AE1′ to AE3′. A region overlapping the pixel definition layer PDL′ may be understood as a boundary region BDA between neighboring sub-pixels.

The pixel definition layer PDL′ may include a plurality of inorganic insulating layers which are sequentially stacked. Each of the plurality of inorganic insulating layers may each include at least one selected from silicon oxide (SiOₓ) and silicon nitride (SiNₓ). However, embodiments are not limited thereto. In an embodiment, for example, the pixel definition layer PDL′ may include an organic insulating layer.

In an embodiment, the pixel definition layer PDL′ may include first, second, third, and fourth inorganic insulating layers ISL1′, ISL2′, ISL3′, and ISL4′. The first inorganic insulating layer ISL1′ may cover a part of each of the first to third anode electrodes AE1′ to AE3′ and the via layer VIAL. The second inorganic insulating layer ISL2′ is disposed on the first inorganic insulating layer ISL1′, the third inorganic insulating layer ISL3′ is disposed on the second inorganic insulating layer ISL2′, and the fourth inorganic insulating layer ISL4′ is disposed on the third inorganic insulating layer ISL3′. The first and third inorganic insulating layers ISL1′ and ISL3′ may each include silicon nitride (SiNₓ), and the second and fourth inorganic insulating layers ISL2′ and ISL4′ may each include silicon oxide (SiOₓ), but embodiments are not limited thereto. In another embodiment, the first inorganic insulating layer ISL1′ may be omitted.

The pixel definition layer PDL′ may include a separator SPR′ in the boundary region BDA between neighboring sub-pixels. The separator SPR′ may cause a discontinuous portion, such as a void VD′, to be formed in the light emitting structure EMS′. Due to the discontinuous portion, at least some of a plurality of layers included in the light emitting structure EMS' may be disconnected or bent.

The fourth inorganic insulating layer ISL4′ may have a greater width than widths of the second and third inorganic insulating layers ISL2′ and ISL3′. In an embodiment, side surfaces of the second to fourth inorganic insulating layers ISL2′ to ISL4′ adjacent to the openings OP′ may be provided as the separators SPR′.

Referring to FIG. 15 together with FIG. 14, the fourth inorganic insulating layer ISL4′ may include first to third portions P1 to P3. The second portion P2 may completely overlap the second and third inorganic insulating layers ISL2′ and ISL3′. The first portion P1 protrudes from the second portion P2 in a direction opposite to the first direction DR1. The third portion P3 protrudes from the second portion P2 in the first direction DR1. In such an embodiment, a width of the fourth inorganic insulating layer ISL4′ may be greater than widths of the second and third inorganic insulating layers ISL2′ and ISL3′. In an embodiment, for example, during a manufacturing process, the second and third inorganic insulating layers ISL2′ and ISL3′ may be undercut so as not to include a portion overlapping the first and third portions P1 and P3. In an embodiment, for example, each of the first and third portions P1 and P3 of the fourth inorganic insulating layer ISL4′ may have a shape of eaves over the second and third inorganic insulating layers ISL2′ and ISL3′.

In the boundary region BDA, the second and third inorganic insulating layers ISL2′ and ISL3′ may have the same width. However, embodiments are not limited thereto, and the second and third inorganic insulating layers ISL2′ and ISL3′ may have different widths. In an embodiment, for example, the second inorganic insulating layer ISL2′ may have a greater width than a width of the third inorganic insulating layer ISL3′. In another embodiment, for example, the third inorganic insulating layer ISL3′ may have a greater width than the width of the second inorganic insulating layer ISL2′.

In the second sub-pixel SP2, the first portion P1 of the fourth inorganic insulating layer ISL4′ and first side surfaces SSF1 of the second and third inorganic insulating layers ISL2′ and ISL3′) may be provided as one separator SPR′. Accordingly, a first void VD1′ adjacent to the first portion P1 of the fourth inorganic insulating layer ISL4′ may be formed in the light emitting structure EMS′. In the third sub-pixel SP3, the third portion P3 of the fourth inorganic insulating layer ISL4′ and second side surfaces SSF2 of the second and third inorganic insulating layers ISL2′ and ISL3′ may be provided as another separator SPR′. Accordingly, a second void VD2′ adjacent to the third portion P3 of the fourth inorganic insulating layer ISL4′ may be formed in the light emitting structure EMS′.

Some of a plurality of layers stacked in the light emitting structure EMS' may be disconnected or bent by the first and second voids VD1′ and VD2′. In an embodiment, for example, at least one charge generation layer and at least one hole injection layer included in the light emitting structure EMS' may be disconnected by the first and second voids VD1′ and VD2′. In such an embodiment, due to the separator SPR′, parts of the light emitting structure EMS' included in the first to third sub-pixels SP1 to SP3 may be at least partially separated from each other.

The pixel definition layer PDL′ may include an additional separator such that the light emitting structure EMS' further includes a discontinuous portion in the boundary region BDA. In an embodiment, the pixel definition layer PDL′ may include one or more trenches as separators in the boundary region BDA. The one or more trenches may penetrate one or more of the first to fourth inorganic insulating layers ISL1′ to ISL4′. Due to the one or more trenches, some of a plurality of layers stacked in the light emitting structure EMS′, for example, at least one charge generation layer and at least one hole injection layer, may be disconnected or bent. In an embodiment, the light emitting structure EML may have a structure in which three light emitting units, each including a light emitting layer, are stacked, and two charge generation layers may be disposed between the three light emitting units. In an embodiment, the pixel definition layer PDL′ may include one or more trenches in the boundary region BDA.

Referring back to FIG. 14, the light emitting structure EMS' may be disposed on the anode electrodes AE exposed by the opening OP′ of the pixel definition layer PDL′. The light emitting structure EMS' may be disposed entirely over the first to third sub-pixels SP1 to SP3 while filling the openings OP′ of the pixel definition layer PDL′. As described above, the light emitting structure EMS' may be disconnected or bent by the separator SPR′ in the boundary region BDA or in a region adjacent to the boundary region BDA. Accordingly, when the display panel 110 operates, a current flowing from each of the first to third sub-pixels SP1 to SP3 to neighboring sub-pixels through layers included in the light emitting structure EMS' may be reduced. Therefore, the first to third light emitting elements LD1′ to LD3′ may operate with relatively high reliability.

In an embodiment, the light emitting structure EMS' may include two light emitting units sequentially stacked, each of which may include a light emitting layer configured to generate light according to an applied current. In another embodiment, the light emitting structure EMS' may include three light emitting units sequentially stacked, each of which may include a light emitting layer configured to generate light according to an applied current. In an embodiment, a charge generation layer may be disposed between the light emitting units.

In an embodiment, the light emitting structure EMS' may be formed through processes, such as vacuum deposition, inkjet printing, or the like.

The cathode electrode CE may be disposed on the light emitting structure EMS′. The cathode electrode CE may be provided in common to the first to third sub-pixels SP1 to SP3.

The first anode electrode AE1′, a portion of a light emitting structure EMS' which overlaps the first anode electrode AE1′, and a portion of the cathode electrode CE which overlaps the first anode electrode AE1′ may configure the first light emitting element LD1′. The second anode electrode AE2′, a portion of the light emitting structure EMS' which overlaps the second anode electrode AE2′, and a portion of the cathode electrode CE which overlaps the second anode electrode AE2′ may configure the second light emitting element LD2′. The third anode electrode AE3′, a portion of the light emitting structure EMS' which overlaps the third anode electrode AE3′, and a portion of the cathode electrode CE which overlaps the third anode electrode AE3′ may configure the third light emitting element LD3′.

An encapsulation layer TFE is disposed on the cathode electrode CE. The encapsulation layer TFE may effectively prevent oxygen, moisture, or the like from permeating into the light emitting element layer LDL′.

An adhesive layer APL, an optical function layer OFL, an overcoat layer OC, and a cover window CW are disposed over the encapsulation layer TFE. The adhesive layer APL, the optical function layer OFL, the overcoat layer OC, and the cover window CW are respectively configured in a same manner as the adhesive layer APL, the optical function layer OFL, the overcoat layer OC, and the cover window CW of FIG. 13, respectively. Any repetitive detailed descriptions thereof are omitted.

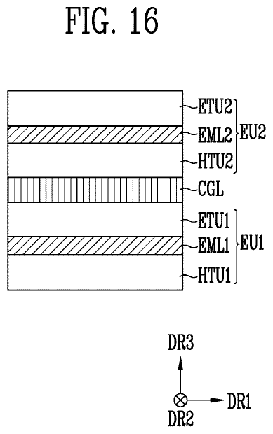

FIG. 16 is a cross-sectional view illustrating an embodiment of a part of a light emitting structure included in one of the first to third light emitting elements of FIG. 13 or FIG. 14.

Referring to FIG. 16, in an embodiment, the light emitting structure may have a tandem structure in which first and second light emitting units EU1 and EU2 are stacked. The light emitting structure may be configured to be substantially identical to the light emitting structure of each of the first to third light emitting elements LD1 to LD3 of FIG. 13.

Each of the first and second light emitting units EU1 and EU2 may include at least one light emitting layer that generates light according to an applied current. The first light emitting unit EU1 may include a first light emitting layer EML1, a first electron transfer unit ETU1, and a first hole transfer unit HTU1. The first light emitting layer EML1 may be disposed between the first electron transfer unit ETU1 and the first hole transfer unit HTU1. The second light emitting unit EU2 may include a second light emitting layer EML2, a second electron transfer unit ETU2, and a second hole transfer unit HTU2. The second light emitting layer EML2 may be disposed between the second electron transfer unit ETU2 and the second hole transfer unit HTU2.

Each of the first and second hole transfer units HTU1 and HTU2 may include at least one selected from a hole injection layer and a hole transfer layer, and may further include a hole buffer layer, an electron blocking layer, or the like, as desired. The first and second hole transfer units HTU1 and HTU2 may have a same configuration as each other or different configurations from each other.

Each of the first and second electron transfer units ETU1 and ETU2 may include at least one selected from an electron injection layer and an electron transfer layer, and may further include an electron buffer layer, a hole blocking layer, or the like, as desired. The first and second electron transfer units ETU1 and ETU2 may have a same configuration as each other or different configurations from each other.

A connection layer, which may be provided in the form of a charge generation layer CGL, may be disposed between the first light emitting unit EU1 and the second light emitting unit EU2 to connect the first light emitting unit EU1 to the second light emitting unit EU2. In an embodiment, the charge generation layer CGL may have a stacked structure of a p-dopant layer and an n-dopant layer. In an embodiment, for example, the p-dopant layer may include a p-type dopant, such as HAT-CN, TCNQ, or NDP-9, and the n-dopant layer may include an alkali metal, an alkaline earth metal, a lanthanide metal, or a combination thereof. However, embodiments are not limited thereto.

In the embodiment, the first light emitting layer EML1 and the second light emitting layer EML2 may generate light of different colors from each other. The lights emitted from the first light emitting layer EML1 and the second light emitting layer EML2 may be mixed together and recognized as white light. In an embodiment, for example, the first light emitting layer EML1 may generate blue light, and the second light emitting layer EML2 may generate yellow light. In an embodiment, the second light emitting layer EML2 may have a structure in which a first sub-emission layer configured to generate red light and a second sub-emission layer configured to generate green light are stacked. The red light and the green light may be mixed together to provide yellow light. In such an embodiment, an intermediate layer, which is configured to perform a function of transferring holes and/or a function of blocking transfer of electrons, may be further disposed between the first and second sub-emission layers.

In another embodiment, the first light emitting layer EML1 and the second light emitting layer EML2 may generate light of the same color.

The light emitting structure may be formed through a method, such as vacuum deposition, inkjet printing, or on the like, but embodiments are not limited thereto.

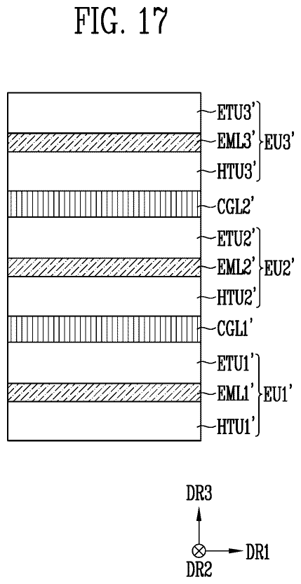

FIG. 17 is a cross-sectional view illustrating another embodiment of a part of the light emitting structure included in any one of the first to third emitting elements LD1 to LD3 of FIG. 13 or FIG. 14.

Referring to FIG. 17, in an embodiment, the light emitting structure may have a tandem structure in which first to third emitting units EU1′ to EU3′ are stacked. The light emitting structures of the first to third emitting elements LD1 to LD3 of FIG. 13 may be configured substantially the same as each other.

The first to third light emitting units EU1′ to EU3′ may each include a light emitting layer that generates light according to an applied current. The first light emitting unit EU1′ may include a first light emitting layer EML1′, a first electron transfer unit ETU1′, and a first hole transfer unit HTU1′. The first light emitting layer EML1′ may be disposed between the first electron transfer unit ETU1′ and the first hole transfer unit HTU1′. The second light emitting unit EU2′ may include a second light emitting layer EML2′, a second electron transfer unit ETU2′, and a second hole transfer unit HTU2′. The second light emitting layer EML2′ may be disposed between the second electron transfer unit ETU2′ and the second hole transfer unit HTU2′. The third light emitting unit EU3′ may include a third light emitting layer EML3′, a third electron transfer unit ETU3′, and a third hole transfer unit HTU3′. The third light emitting layer EML3′ may be disposed between the third electron transfer unit ETU3′ and the third hole transfer unit HTU3′.

The first to third hole transfer units HTU1′ to HTU3′ may each include at least one selected from a hole injection layer and a hole transfer layer and may further include a hole buffer layer, an electron blocking layer, or the like, as desired. The first to third hole transfer units HTU1′ to HTU3′ may have either a same configuration as each other or different configurations from each other.

The first to third electron transfer units ETU1′ to ETU3′ may each include at least one selected from an electron injection layer and an electron transfer layer and may further include an electron buffer layer, a hole blocking layer, or the like, as desired. The first to third electron transfer units ETU1′ to ETU3′) may have either a same configuration as each other or different configurations from each other.

A first charge generation layer CGL1′ is disposed between the first light emitting unit EU1′ and the second light emitting unit EU2′. A second charge generation layer CGL2′ is disposed between the second light emitting unit EU2′ and the third light emitting unit EU3′.

In an embodiment, the first to third light emitting layers EML1′ to EML3′ may generate light of different colors. The light emitted from the first light emitting layer EML1′ to the light emitted from the third light emitting layer EML3′ may be mixed together and recognized as white light. In an embodiment, for example, the first light emitting layer EML1′ may generate blue light, the second light emitting layer EML2′ may generate green light, and the third light emitting layer EML3′ may generate red light.

In another embodiment, two or more of the first to third light emitting layers EML1′ to EML3′ may generate light of a same color.

In another embodiment, the first to third light emitting elements LD1 to LD3 included in the light emitting structure of FIG. 13 or FIG. 14 may also each include a single light emitting unit. In such an embodiment, the light emitting units included in the first to third light emitting elements LD1 to LD3 may be configured to emit lights of different colors. In an embodiment, for example, the light emitting unit of the first light emitting element LD1 may emit red light, the light emitting unit of the second light emitting element LD2 may emit green light, and the light emitting unit of the third light emitting element LD3 may emit blue light. In such an embodiment, the light emitting units of the first to third sub-pixels SP1 to SP3 may be separated from each other and may each be disposed in the opening OP (see FIG. 13) of the pixel definition layer PDL (see FIG. 13) or the opening OP′ (see FIG. 14) of the pixel definition layer PDL′ (see FIG. 14). In such an embodiment, at least some of the color filters CF1 to CF3 may be omitted.

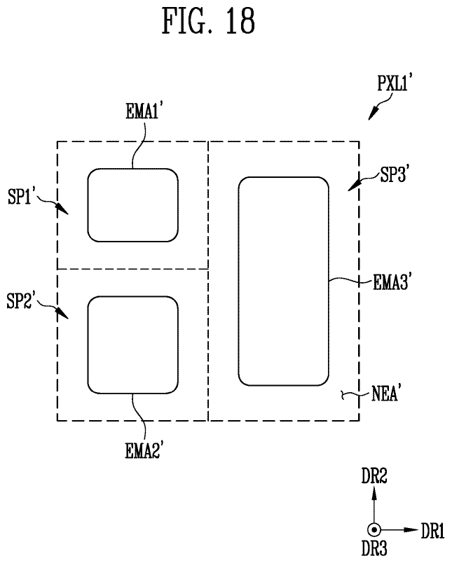

FIG. 18 is a plan view illustrating another embodiment of one of the pixels of FIG. 11.

Referring to FIG. 18, in an embodiment, a first pixel PXL1′ may include first, second, and third sub-pixels SP1′, SP2′, and SP3′.

The first sub-pixel SP1′ may include a first light emitting region EMA1′ and a non-light emitting region NEA′ surrounding the first light emitting region EMA1′. The second sub-pixel SP2′ may include a second light emitting region EMA2′ and a non-light emitting region NEA′ surrounding the second light emitting region EMA2′. The third sub-pixel SP3′ may include a third light emitting region EMA3′ and a non-light emitting region NEA′ surrounding the third light emitting region EMA3′.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′.

The second sub-pixel SP2′ may have a greater area than the first sub-pixel SP1′, and the third sub-pixel SP3′ may have a greater area than the second sub-pixel SP2′. Accordingly, the second light emitting region EMA2′ may have a greater area than the first light emitting region EMA1′, and the third light emitting region EMA3′ may have a greater area than the second light emitting region EMA2′. However, embodiments are not limited thereto. In an embodiment, for example, the first and second sub-pixels SP1′ and SP2′ may have substantially a same area as each other, and the third sub-pixel SP3′ may have a greater area than each of the first and second sub-pixels SP1′ and SP2′. In such an embodiment, areas of the first to third sub-pixels SP1′ to SP3′ may be variously changed.

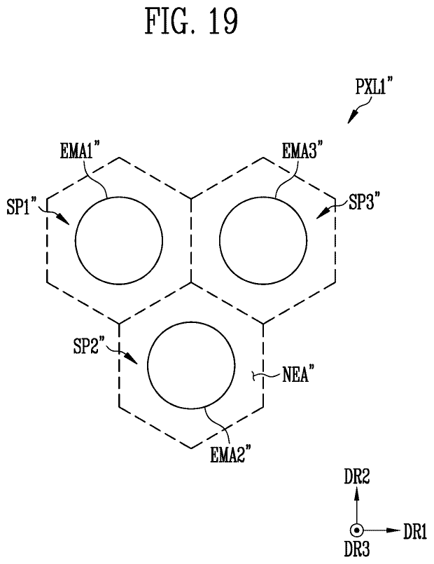

FIG. 19 is a plan view illustrating another embodiment of one of the pixels of FIG. 11.

Referring to FIG. 19, in an embodiment, a first sub-pixel SP1″ may include a first light emitting region EMA1″ and a non-light emitting region NEA″ surrounding the first light emitting region EMA1″. A second sub-pixel SP2″ may include a second light emitting region EMA2″ and a non-light emitting region NEA″ surrounding the second light emitting region EMA2″. A third sub-pixel SP3″ may include a third light emitting region EMA3″ and a non-light emitting region NEA″ surrounding the third light emitting region EMA3″.

The first to third sub-pixels SP1″ to SP3″ may each have a polygonal shape when viewed in the third direction DR3. In an embodiment, for example, the shape of each of the first to third sub-pixels SP1″ to SP3″ may be a hexagonal shape as illustrated in FIG. 19.

The first to third light emitting regions EMA1″ to EMA3″ may each have a circular shape when viewed in the third direction DR3. However, embodiments are not limited thereto. In an embodiment, for example, each of the first to third light emitting regions EMA1″ to EMA3″ may each have a polygonal shape.

The first and third sub-pixels SP1″, SP3″ may be arranged in the first direction DR1. The second sub-pixel SP2″ may be disposed in a direction (or diagonal direction) that is inclined at an acute angle in the second direction DR2 with respect to the first sub-pixel SP1″.

The arrangements of the sub-pixels illustrated in FIGS. 12, 18, and 19 are examples, and embodiments are not limited thereto. Each pixel includes two or more sub-pixels, the sub-pixels may be arranged in various ways, each of the sub-pixels may have various shapes, and each of light emitting regions of the sub-pixels may also have various shapes.

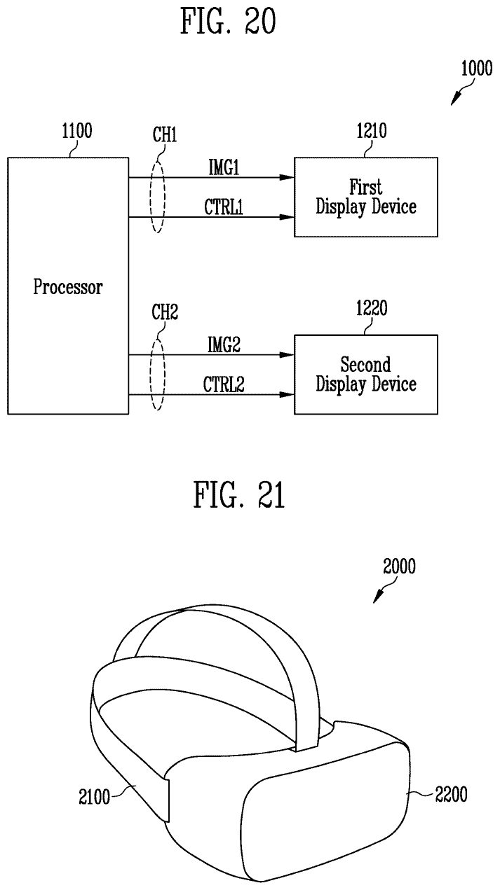

FIG. 20 is a block diagram illustrating an embodiment of a display system.

Referring to FIG. 20, a display system 1000 may include a processor 1100 and one or more display devices 1210 and 1220.

The processor 1100 may perform various tasks and calculations. In the embodiment, the processor 1100 may include an application processor, a graphics processor, a microprocessor, a central processing unit (CPU), or the like. The processor 1100 may be connected to other components of the display system 1000 through a bus system and control the components.

FIG. 20 illustrates that the display system 1000 includes first and second display devices 1210 and 1220. The processor 1100 may be connected to the first display device 1210 through a first channel CH1 and to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured similarly to the display device 100 described above with reference to FIG. 1. In such an embodiment, the first image data IMG1 and the first control signal CTRL1 may be provided respectively as the input image data IMG and the control signal CTRL of FIG. 1.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured similarly to the display device 100 described above with reference to FIG. 1. In such an embodiment, the second image data IMG2 and the second control signal CTRL2 may be provided respectively as the input image data IMG and the control signal CTRL of FIG. 1.

The display system 1000 may include a computing system, which provides an image display function, such as a portable computer, a mobile phone, a smartphone, a tablet personal computer, a smart watch, a watch phone, a portable multimedia player (PMP), a navigation system, or an ultramobile personal computer (UMPC). In addition, the display system 1000 may include at least one of a head mounted display (HMD), a virtual reality (VR) device, a mixed reality (MR) device, and an augmented reality (AR) device.

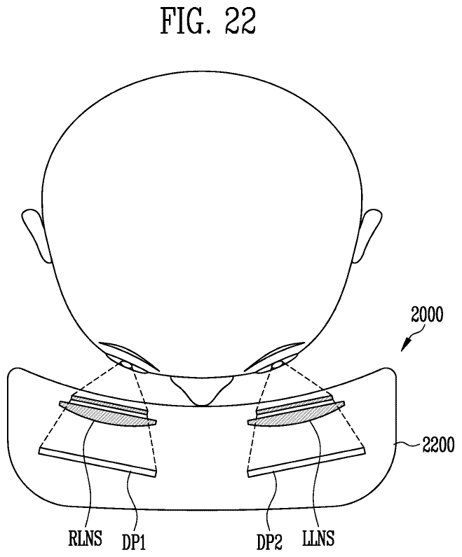

FIG. 21 is a perspective view illustrating an application example of the display system of 1000 FIG. 20.

Referring to FIG. 21, the display system 1000 of FIG. 20 may be applied to a head mounted display device 2000. The head mounted display device 2000 may be a wearable electronic device that may be worn on a user's head.

The head mounted display device 2000 may include a head mounted band 2100 and a display device storage case 2200. The head mounted band 2100 may be connected to the display device storage case 2200. The head mounted band 2100 may include a horizontal band and/or a vertical band for fixing the head mounted display device 2000 to a user's head. The horizontal band may be configured to surround a side portion of the user's head, and the vertical band may be configured to surround an upper portion of the user's head. However, embodiments are not limited thereto. In an embodiment, for example, the head mounted band 2100 may also be implemented in the form of a glasses frame, a helmet, or so on.

The display device storage case 2200 may store the first and second display devices 1210 and 1220 of FIG. 20. The display device storage case 2200 may further store the processor 1100 of FIG. 20.

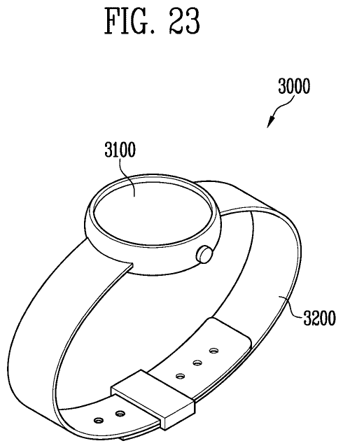

FIG. 22 is a view illustrating a head mounted display device which is worn by a user and illustrated in FIG. 21.

Referring to FIG. 22, a first display panel DP1 of the first display device 1210 and a second display panel DP2 of the second display device 1220 are disposed in the head mounted display device 2000. The head mounted display device 2000 may further include one or more lenses, that is a right eye lens RLNS and a left eye lens LLNS.

In the display device storage case 2200, the right eye lens RLNS may be disposed between the first display panel DP1 and a user's right eye. In the display device storage case 2200, the left eye lens LLNS may be disposed between the second display panel DP2 and the user's left eye.

An image output from the first display panel DP1 may be shown to the user's right eye through the right eye lens RLNS. The right eye lens RLNS may refract the light from the first display panel DP1 toward the user's right eye. The right eye lens RLNS may perform an optical function for adjusting a viewing distance between the first display panel DP1 and the user's right eye.

An image output from the second display panel DP2 may be shown to the user's left eye through the left eye lens LLNS. The left eye lens LLNS may refract the light from the second display panel DP2 toward the user's left eye. The left eye lens LLNS may perform an optical function for adjusting a viewing distance between the second display panel DP2 and the user's left eye.

In an embodiment, each of the right eye lens RLNS and the left eye lens LLNS may include an optical lens having a cross-section in a pancake shape. In an embodiment, each of the right eye lens RLNS and the left eye lens LLNS may include a multi-channel lens including sub-regions with different optical characteristics. In such an embodiment, each display panel outputs images corresponding to sub-regions of the multi-channel lens, and the output images may be shown to the user by passing through the corresponding sub-regions.

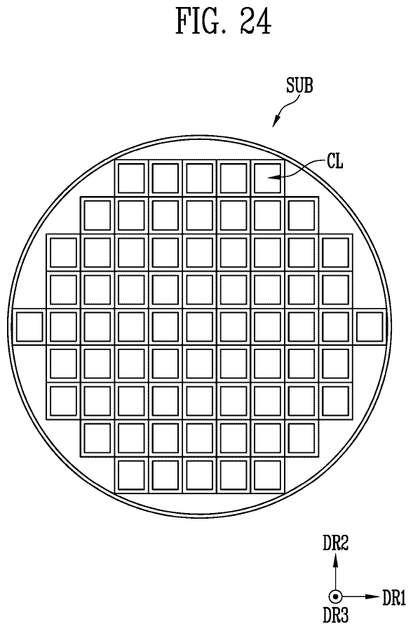

FIG. 23 is a perspective view illustrating another application example of the display system of FIG. 20.

Referring to FIG. 23, the display system 1000 of FIG. 20 may be applied to a smart watch 3000 including a display unit 3100 and a strap unit 3200.

The smart watch 3000 may be a wearable electronic device. In an embodiment, for example, the smart watch 3000 may have a structure in which the strap unit 3200 is mounted on a user's wrist. Here, the display system 1000 may be applied to the display unit 3100, and accordingly, image data including time information may be provided to a user.

Subsequently, a method of forming a marking code of the display device according to the above-described embodiment will be described.

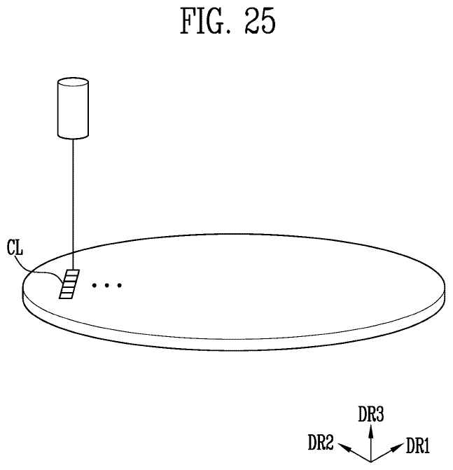

FIGS. 24 and 25 are cross-sectional views of respective processes of a manufacturing method of a display device.

FIGS. 24 and 25 are cross-sectional views illustrating a method of forming a marking code according to an embodiment, the cross-sectional views are briefly illustrated, and detailed symbols thereof are omitted for convenience of illustration and description.

Referring to FIG. 24, in an embodiment of a method of forming a marking code, a substrate SUB is first prepared. The substrate SUB may be a silicon wafer substrate. The substrate SUB may include cells CL. Each of the cells CL may form the base layer BSL of the display panel DP described above. The cells CL may be formed by cutting the substrate SUB. The cells CL may be separated from each other on the substrate SUB and may be arranged in a matrix form but are not limited thereto.

Subsequently, referring to FIG. 25, the marking code MC (see FIGS. 4 to 8) is formed on each of the cells CL of the substrate SUB. The marking code MC may be marked before the cells CL are cut. The marking code MC may be formed directly on a surface of the substrate SUB through laser annealing. In such an embodiment, the marking code MC is formed through the laser annealing, such that laser residue may be prevented from being generated. Accordingly, as described above, it is possible to effectively prevent contamination or particles from being generated due to laser residue and to effectively prevent a recognition rate of the marking code MC from being reduced.

A laser apparatus may be located above the substrate SUB, which is a marking target, to be movable and may include a laser head that emits a laser for marking. In an embodiment, a wavelength of the laser may be in a range of about 248 nm to about 355 nm but is not limited thereto. A surface of the substrate SUB may be recrystallized by laser annealing to form dot patterns MD including the embossed pattern MD1 (e.g., see FIG. 7) and the engraved pattern MD2 (e.g., see FIG. 7). In an embodiment, for example, the depth D2 of the engraved pattern MD2 in the third direction DR3 may be formed to be greater than the height H1 of the positive pattern MD1 in the third direction DR3. The height H1 of the embossed pattern MD1 in the third direction DR3 may be formed to be less than about 0.5 μm, and the depth D2 of the engraved pattern MD2 in the third direction DR3 may be formed to be less than about 1 μm. If the height H1 of the embossed pattern MD1 in the third direction DR3 is formed to be greater than about 0.5 μm or the depth D2 of the engraved pattern MD2 in the third direction DR3 is formed to be greater than about 1 μm, contamination may be generated due to laser residue, causing particles or reducing a recognition rate of the marking code MC. The marking code MC is substantially the same as that described above with reference to FIGS. 4 to 8, and accordingly, any repetitive detailed descriptions thereof will be omitted.

Next, the substrate SUB is cut to separate respective cells CL and complete the display panel DP.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a base layer including a marking code;
a first electrode on the base layer;
a light emitting structure on the first electrode; and
a second electrode on the light emitting structure,
wherein the marking code includes dot patterns including an embossed pattern and an engraved pattern, and
a depth of the engraved pattern with respect to a surface of the base layer is greater than a height of the embossed pattern with respect to the surface of the base layer.

2. The display device of claim 1, wherein
the height of the embossed pattern is less than about 0.5 μm.

3. The display device of claim 1, wherein
the depth of the engraved pattern is less than about 1 μm.

4. The display device of claim 1, wherein
a width of each of the dot patterns is in a range of about 8 μm to about 12 μm.

5. The display device of claim 1, wherein
an interval between the dot patterns is about 1.2 μm or less.

6. The display device of claim 1, wherein
the dot patterns are arranged in a first direction and a second direction intersecting the first direction.

7. The display device of claim 1, wherein
the embossed pattern surrounds the engraved pattern on a plane.

8. The display device of claim 1, wherein
the base layer is a silicon substrate.

9. The display device of claim 1, further comprising:
a pixel definition layer between the first electrode and the light emitting structure.

10. The display device of claim 9, wherein
the light emitting structure is disposed entirely on the first electrode and the pixel definition layer.

11. The display device of claim 9, wherein
the pixel definition layer includes a separator.

12. The display device of claim 11, wherein
the light emitting structure is at least partially separated by the separator.

13. The display device of claim 1, wherein
ash, burrs, and/or particles do not exist in the marking code.

14. A substrate comprising:
a marking code including dot patterns including an embossed pattern and an engraved pattern,
wherein a depth of the engraved pattern with respect a surface of the substrate is greater than a height of the embossed pattern with respect the surface of the substrate.

15. The substrate of claim 14, wherein
the height of the embossed pattern is less than about 0.5 μm.

16. The substrate of claim 14, wherein
the depth of the engraved pattern is less than about 1 μm.

17. The substrate of claim 14, wherein
the dot patterns are arranged in a first direction and a second direction intersecting the first direction.

18. The substrate of claim 14, wherein
the embossed pattern surrounds the engraved pattern on a plane.

19. The substrate of claim 14, wherein
ash, burrs, and/or particles do not exist in the marking code.

20. An electronic device comprising:
a processor to provide input image data; and
a display device to display an image based on the input image data, the display device including sub-pixel areas,
wherein the display device comprises:
a base layer including a marking code;
a first electrode on the base layer;
a light emitting structure on the first electrode; and
a second electrode on the light emitting structure,
wherein the marking code includes dot patterns including an embossed pattern and an engraved pattern, and
a depth of the engraved pattern with respect to a surface of the base layer is greater than a height of the embossed pattern with respect to the surface of the base layer.
